(19) United States
(12) Patent Application Publication
(10) Pub. No.: US 2024/0162275 A1
(43) Pub. Date: May 16, 2024

(54) DISPLAY DEVICE AND METHOD OF FABRICATING THE SAME

(71) Applicant: Samsung Display Co., Ltd., Yongin-si (KR)

(72) Inventors: Soo Chul KIM, Yongin-si (KR); Tae Gyun KIM, Yongin-si (KR); Sung Won CHO, Yongin-si (KR); Jin Taek PARK, Yongin-si (KR); Jae Ho CHOI, Yongin-si (KR)

(21) Appl. No.: 18/475,040

(22) Filed: Sep. 26, 2023

(30) Foreign Application Priority Data
Nov. 10, 2022 (US) 10-2022-0149228

(51) Int. Cl. H01L 27/15

(52) U.S. Cl. CPC H01L 27/156

(57) ABSTRACT

A display device includes a plurality of pixel electrodes on a substrate, light-emitting elements on the plurality of pixel electrodes and extending in a thickness direction of the substrate and connecting electrodes between the plurality of pixel electrodes and the light-emitting elements, wherein a width of the connecting electrodes is greater than a width of the light-emitting elements, and upper corners of each of the light-emitting elements and upper corners of each of the connecting electrodes are rounded.

### CROSS-REFERENCE TO RELATED APPLICATION

This application claims priority to and the benefit of Korean Patent Application No. 10-2022-0149228, filed on Nov. 10, 2022, in the Korean Intellectual Property Office, the entire content of which is incorporated by reference herein.

### BACKGROUND

### 1. Field

The present disclosure relates to a display device and a method of fabricating the same.

### 2. Description of the Related Art

Display devices are becoming more important with developments in multimedia technology. Accordingly, various display devices such as an organic light-emitting diode (OLED) display device, a liquid crystal display (LCD) device, and the like have been used.

Typically, a display device includes a display panel such as an organic light-emitting display panel or an LCD panel. A light-emitting display panel may include light-emitting elements such as, for example, light-emitting diodes (LEDs). Examples of the LEDs include organic LEDs (OLEDs) using an organic material as a light-emitting material and inorganic LEDs using an inorganic material as a light-emitting material.

### SUMMARY

Aspects and features of embodiments of the present disclosure provide a display device capable of preventing sidewalls from being formed on each light-emitting element due to a rearrangement phenomenon that may occur when forming connecting electrodes by etching a connecting electrode layer having a nonvolatile property during the formation of light-emitting elements by bonding a light-emitting material layer on a circuit substrate, and a method of fabricating the display device.

However, aspects and features of embodiments of the present disclosure are not restricted to those set forth herein. The above and other aspects and features of the present disclosure will become more apparent to one of ordinary skill in the art to which the present disclosure pertains by referencing the detailed description of the present disclosure given below.

According to one or more embodiments of the present disclosure, a display device includes a plurality of pixel electrodes on a substrate, light-emitting elements on the plurality of pixel electrodes and extending in a thickness direction of the substrate and connecting electrodes between the plurality of pixel electrodes and the light-emitting elements, wherein a width of the connecting electrodes is greater than a width of the light-emitting elements, and upper corners of each of the light-emitting elements and upper corners of each of the connecting electrodes are rounded.

Corners at boundaries between the connecting electrodes and the light-emitting elements are rounded.

The connecting electrodes include a nonvolatile material including one or more selected from among gold (Au), copper (Cu), silver (Ag), and roentgenium (Rg).

The display device further includes a first insulating layer between the pixel electrodes, wherein the first insulating layer has a stepped structure.

The first insulating layer includes first areas overlapping with the connecting electrodes and second areas not overlapping with the connecting electrodes, and a thickness of the first areas is greater than a thickness of the second areas.

The display device further includes a second insulating layer covering a top surface and side surfaces of each of the light-emitting elements, parts of top surfaces of the connecting electrodes not overlapping the light-emitting elements, and side surfaces of each of the connecting electrodes, wherein the second insulating layer includes openings at the top surfaces of the light-emitting elements and further includes upper corners corresponding to the upper corners of each of the light-emitting elements and inclined parts at corners corresponding to the upper corners of each of the connecting electrodes.

The display device further includes a common electrode on the second insulating layer, wherein the common electrode is in contact with the light-emitting elements through the openings and includes upper corners corresponding to the upper corners of each of the light-emitting elements and inclined parts at corners corresponding to the upper corners of each of the connecting electrodes.

Each of the light-emitting elements includes a first semiconductor layer, an electron blocking layer, an active layer, a superlattice layer, and a second semiconductor layer that are sequentially stacked in a third direction.

According to one or more embodiments of the present disclosure, method of fabricating a display device includes bonding a first substrate in which a plurality of pixel electrodes is located, and a second substrate on which a light-emitting material layer is located, with a connecting electrode layer and removing the second substrate, forming hard mask patterns having a stepped structure on the light-emitting material layer, forming light-emitting elements and connecting electrodes by etching the light-emitting material layer along the hard mask patterns and depositing a common electrode on the light-emitting elements, wherein the hard mask patterns include middle parts and edge parts located along peripheries of the middle parts, and a thickness of the middle parts is greater than a thickness of the edge parts.

The method further includes before the depositing the common electrode, forming a second insulating layer to cover a top surface and side surfaces of each of the light-emitting elements and a top surface and side surfaces of each of the connecting electrodes, wherein the second insulating layer includes openings at the top surfaces of the light-emitting elements, and the common electrode is in contact with the top surfaces of the light-emitting elements through the openings.

The connecting electrodes includes a nonvolatile material including one or more selected from among gold (Au), copper (Cu), silver (Ag), and roentgenium (Rg).

The forming the light-emitting elements and the connecting electrodes, includes defining light-emitting element regions by performing a primary etching process on the light-emitting material layer until the edge parts are removed, defining connecting electrode regions by performing a secondary etching process on the connecting electrode layer, and forming the light-emitting elements and the connecting electrodes by performing a tertiary etching process on the light-emitting material layer and the connecting electrode regions.

A width of the connecting electrodes is greater than a width of the light-emitting elements, and upper corners of each of the light-emitting elements and upper corners of each of the connecting electrodes are rounded.

The first substrate further includes a first insulating layer between the pixel electrodes, and the first insulating layer is formed to have a stepped structure by the tertiary etching process.

The first insulating layer includes first areas overlapping with the connecting electrodes and second areas not overlapping with the connecting electrodes, and a thickness of the first areas is greater than a thickness of the second areas.

The method further includes before the depositing the common electrode on the light-emitting elements, forming a second insulating layer to cover a top surface and side surfaces of each of the light-emitting elements, parts of top surfaces of the connecting electrodes not overlapping the light-emitting elements, and side surfaces of each of the connecting electrodes and to have openings at the top surfaces of the light-emitting elements, wherein the second insulating layer includes upper corners corresponding to the upper corners of each of the light-emitting elements and inclined parts at corners corresponding to the upper corners of each of the connecting electrodes.

Wherein the depositing the common electrode on the light-emitting elements, includes depositing the common electrode on the second insulating layer to be in contact with the light-emitting elements through the openings and to have upper corners corresponding to the upper corners of each of the light-emitting elements and inclined parts at corners corresponding to the upper corners of each of the connecting electrodes.

According to one or more embodiments of the present disclosure, a method of fabricating a display device includes bonding a first substrate in which a plurality of pixel electrodes is located, and a second substrate on which a light-emitting material layer is located, with a connecting electrode layer and removing the second substrate, forming double mask patterns including hard mask patterns and photoresist mask patterns, on the light-emitting material layer, forming light-emitting elements and connecting electrodes by etching the light-emitting material layer along the double mask patterns and depositing a common electrode on the light-emitting elements, wherein the hard mask patterns define light-emitting element regions, and the photoresist mask patterns are formed to surround a top surface and side surfaces of each of the hard mask patterns and define connecting electrode regions.

The method further includes before the depositing the common electrode, forming a second insulating layer covering a top surface and side surfaces of each of the light-emitting elements and a top surface and side surfaces of each of the connecting electrodes, wherein the second insulating layer includes openings at the top surfaces of the light-emitting elements, and the common electrode contacting with the top surfaces of the light-emitting elements through the openings.

The connecting electrodes include a nonvolatile material including one or more selected from among gold (Au), copper (Cu), silver (Ag), and roentgenium (Rg).

The forming the light-emitting elements and the connecting electrodes, includes defining the light-emitting element regions by performing a primary etching process on the light-emitting material layer using the double mask patterns, defining the connecting electrode regions by performing a secondary etching process on the connecting electrode layer, and forming the light-emitting elements and the connecting electrodes by performing a tertiary etching process on the light-emitting material layer and the connecting electrode regions.

The first substrate further includes a first insulating layer between the pixel electrodes, and the first insulating layer is formed to have a stepped structure by the tertiary etching process.

The first insulating layer includes first areas overlapping with the connecting electrodes and second areas not overlapping with the connecting electrodes, and a thickness of the first areas is greater than a thickness of the second areas.

According to one or more embodiments of the present disclosure, a method of fabricating a display device includes bonding a first substrate in which a plurality of pixel electrodes is located, and a second substrate on which a light-emitting material layer is located, with a connecting electrode layer and removing the second substrate, forming photoresist mask patterns having a stepped structure on the light-emitting material layer, forming light-emitting elements and connecting electrodes by etching the light-emitting material layer along the photoresist mask patterns and depositing a common electrode on the light-emitting elements, wherein the photoresist mask patterns include middle parts and edge parts, located along peripheries of the middle parts, and a thickness of the middle parts is greater than a thickness of the edge parts.

The method further includes before the depositing the common electrode, forming a second insulating layer to cover a top surface and side surfaces of each of the light-emitting elements and a top surface and side surfaces of each of the connecting electrodes, wherein the second insulating layer includes openings at the top surfaces of the light-emitting elements, and the common electrode is in contact with the top surfaces of the light-emitting elements through the openings.

The connecting electrodes include a nonvolatile material including one or more selected from among gold (Au), copper (Cu), silver (Ag), and roentgenium (Rg).

The forming the light-emitting elements and the connecting electrodes, includes defining light-emitting element regions by performing a primary etching process on the light-emitting material layer until the edge parts are removed, defining connecting electrode regions by performing a secondary etching process on the connecting electrode layer, and forming the light-emitting elements and the connecting electrodes by performing a tertiary etching process on the light-emitting material layer and the connecting electrode regions.

The method a width of the connecting electrodes is greater than a width of the light-emitting elements, and upper corners of each of the light-emitting elements and upper corners of each of the connecting electrodes are rounded.

The first substrate further includes a first insulating layer between the pixel electrodes, and the first insulating layer is formed to have a stepped structure by the tertiary etching process.

The first insulating layer includes first areas overlapping with the connecting electrodes and second areas not overlapping with the connecting electrodes, and a thickness of the first areas is greater than a thickness of the second areas. According to the aforementioned and other embodiments of the present disclosure, any defects that may be caused by unwanted sidewalls formed on the sides of each light-emitting element due to the rearrangement of an element for forming connecting electrodes can be addressed.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail embodiments thereof with reference to the attached drawings, in which:

FIG. 1A is a plan view of a display device according to one or more embodiments of the present disclosure;

FIG. 1B is an enlarged plan view of an area A of FIG. 1A;

FIG. 2 is a layout view of the circuitry of a display substrate of the display device of FIG. 1A;

FIG. 3 is an equivalent circuit diagram of a pixel of the display device of FIG. 1A;

FIG. 4 is an equivalent circuit diagram of a pixel of a display device according to one or more embodiments of the present disclosure;

FIG. 5 is an equivalent circuit diagram of a pixel of a display device according to one or more embodiments of the present disclosure;

FIG. 6 is a cross-sectional view of part of the display device of FIG. 1A;

FIG. 7 is an enlarged cross-sectional view illustrating a pixel electrode and a light-emitting element according to one or more embodiments of the present disclosure;

FIG. 8 is an enlarged cross-sectional view of a light-emitting element of FIG. 6;

FIG. 9 is a cross-sectional view of a light-emitting element of FIG. 6;

FIG. 10 is an enlarged cross-sectional view of a pixel electrode and a light-emitting element of FIG. 9;

FIG. 11A is a cross-sectional view, taken along the line I-I′ of FIG. 1B, of a display panel according to one or more embodiments of the present disclosure;

FIG. 11B is a cross-sectional view, taken along the line I-I′ of FIG. 1B, of a display panel according to one or more embodiments of the present disclosure;

FIG. 11C is a cross-sectional view, taken along the line I-I′ of FIG. 1B, of a display panel according to one or more embodiments of the present disclosure;

FIG. 12 is a flowchart illustrating a method of fabricating a display device according to one or more embodiments of the present disclosure;

FIGS. 13 through 33 are cross-sectional views illustrating the method of FIG. 12;

FIG. 34 is a flowchart illustrating a method of fabricating a display device according to one or more embodiments of the present disclosure;

FIGS. 35 through 41 are cross-sectional views illustrating the method of FIG. 34;

FIG. 42 is a flowchart illustrating a method of fabricating a display device according to one or more embodiments of the present disclosure;

FIGS. 43 through 48 are cross-sectional views illustrating the method of FIG. 42;

FIGS. 49 through 55 are cross-sectional views illustrating a method of fabricating a display panel using a double mask according to one or more embodiments of the present disclosure; and

FIGS. 56 through 60 are cross-sectional views illustrating a method of fabricating a display panel using a double mask according to one or more embodiments of the present disclosure.

FIG. 61 is an example diagram schematically showing a virtual reality device including a display device according to one or more embodiments;

FIG. 62 is an example diagram schematically showing a smart device including a display device according to one or more embodiments;

FIG. 63 is a diagram of an example schematically showing a vehicle including a display device according to one or more embodiments.

FIG. 64 is a diagram of an example schematically showing a transparent display device including a display device according to one or more embodiments.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that the present disclosure will be thorough and complete, and will fully convey the spirit and scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the present disclosure.

It will be understood that, although the terms “first,” “second,” and the like may be used herein to describe various elements, these elements should not be limited by these terms. These terms are only used to distinguish one element from another element. For instance, a first element discussed below could be termed a second element without departing from the spirit and scope of the present disclosure. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, specific embodiments will be described with reference to the accompanying drawings.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

It will be understood that the terms “contact,” “connected to,” and “coupled to” may include a physical and/or electrical contact, connection, or coupling.

The phrase “at least one of” is intended to include the meaning of “at least one selected from the group of” for the purpose of its meaning and interpretation. For example, “at least one of A and B” or “at least one selected from among A and B” may be understood to mean “A, B, or A and B.”

Unless otherwise defined or implied herein, all terms (including technical and scientific terms) used herein have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and the present disclosure, and should not be interpreted in an ideal or excessively formal sense unless clearly so defined herein.

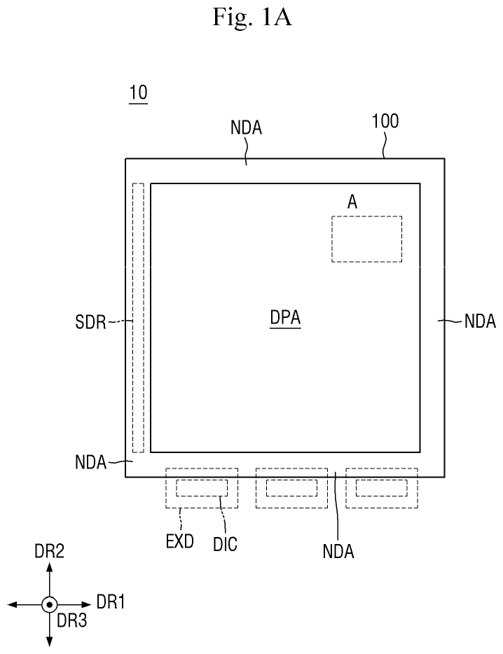

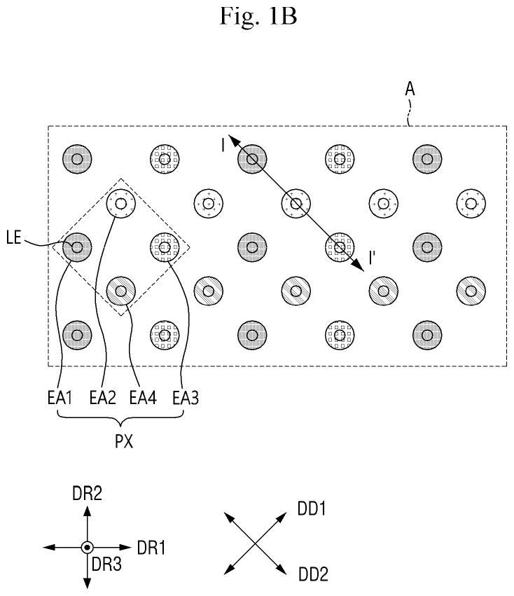

FIG. 1A is a plan view of a display device according to one or more embodiments of the present disclosure, and FIG. 1B is an enlarged plan view of an area A of FIG. 1A.

Referring to FIG. 1A, a display device 10 may be applicable to smartphones, mobile phones, tablet personal computers (PCs), personal digital assistants (PDAs), portable multimedia players (PMPs), televisions (TVs), game consoles, wristwatch-type electronic devices, head-mounted displays, PC monitors, notebook computers, car navigation systems, car dashboards, digital cameras, camcorders, electric billboards, various medical devices, various inspection devices, home appliances (such as refrigerators and washing machines), and/or Internet-of-Things (IoT) devices. The display device 10 will hereinafter be described as being, for example, a TV having a high or ultrahigh resolution such as HD, UHD, 4K, and/or 8K.

The display device 10 may be classified according to how it displays an image. For example, the display device 10 may be an organic light-emitting diode (OLED) display device, an inorganic electro-luminescence (EL) display device, a quantum-dot light-emitting display (QED) device, a micro-light-emitting diode (microLED) display device, a nano-light-emitting diode (nanoLED) display device, a plasma display device (PDP), a field emission display (FED) device, a cathode-ray tube (CRT) device, a liquid crystal display (LCD) device, and/or an electrophoretic display (EPD) device. The display device 10 will hereinafter be described as being, for example, an OLED display device, and an OLED display device will hereinafter be simply referred to as a display device, unless specified otherwise. However, the display device 10 is not limited to an OLED display device, and various other display devices may also be applicable to the display device 10.

A first direction DR1 refers to the horizontal direction of the display device 10, a second direction DR2 refers to the vertical direction of the display device 10, and a third direction DR3 refers to the thickness direction of the display device 10. The terms “left,” “right,” “upper,” and “lower,” as used herein, refer to their respective directions as viewed from above the display device 10. For example, the term “right side” refers to one side in the first direction DR1, the term “left side” refers to the other side in the first direction DR1, the term “upper side” refers to a first side in the second direction DR2, and the term “lower side” refers to a second side in the second direction DR2. The term “top” refers to one side in the third direction DR3, and the term “bottom” refers to the other side in the third direction DR3.

The display device 10 may have, for example, a square shape, in a plan view. In a case where the display device 10 is a TV, the display device 10 may have a rectangular shape whose long sides are aligned in the horizontal direction of the display device 10, but the present disclosure is not limited thereto. Alternatively, the display device 10 may have a rectangular shape whose long sides are aligned in the vertical direction of the display device 10 or may be rotatably installed such that the long sides of the display device 10 are variably aligned in the horizontal or vertical direction of the display device 10. Alternatively, the display device 10 may have a circular or elliptical shape.

The display device 10 may include a display area DPA and a non-display area NDA along an edge or periphery of the display area DPA. The display area DPA may be an active area where the display of an image is performed. The display area DPA may have a similar shape to the display device 10, for example, a square shape, in a plan view, but the present disclosure is not limited thereto.

The display area DPA may include a plurality of pixels PX. The pixels PX may be arranged along row and column directions of a matrix.

The non-display area NDA may be disposed around the display area DPA. The non-display area NDA may surround the entire display area DPA or part of the display area DPA. The display area DPA may have a square shape, and the non-display area NDA may be disposed adjacent to the four sides of the display area DPA. The non-display area NDA may form the bezel of the display device 10.

Driving circuits or driving elements for driving the display area DPA may be disposed in the non-display area NDA. In part of the non-display area NDA adjacent to a first side (or the lower side) of the display device 10, a pad unit may be provided on a display substrate of the display device 10, and an external device EXD may be mounted on pad electrodes in the pad unit. Examples of the external device EXD include a connecting film, a printed circuit board (PCB), a driver integrated chip (DIC), a connector, and a wire connecting film. In part of the non-display area NDA adjacent to a second side (or the left side) of the display device 10, a scan driver SDR, which is directly formed on the display substrate of the display device 10, may be disposed.

Referring to FIG. 1B, the display area DPA of a display panel 100 may include a plurality of pixels PX. The pixels PX may include light-emitting elements LE and may be defined as minimal light-emitting units capable of displaying white light by combining beams of light emitted from the light-emitting elements LE.

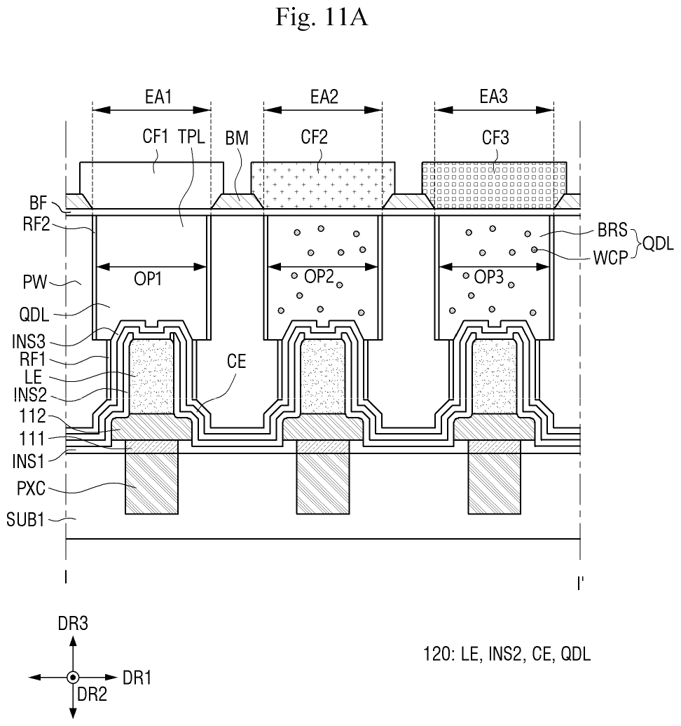

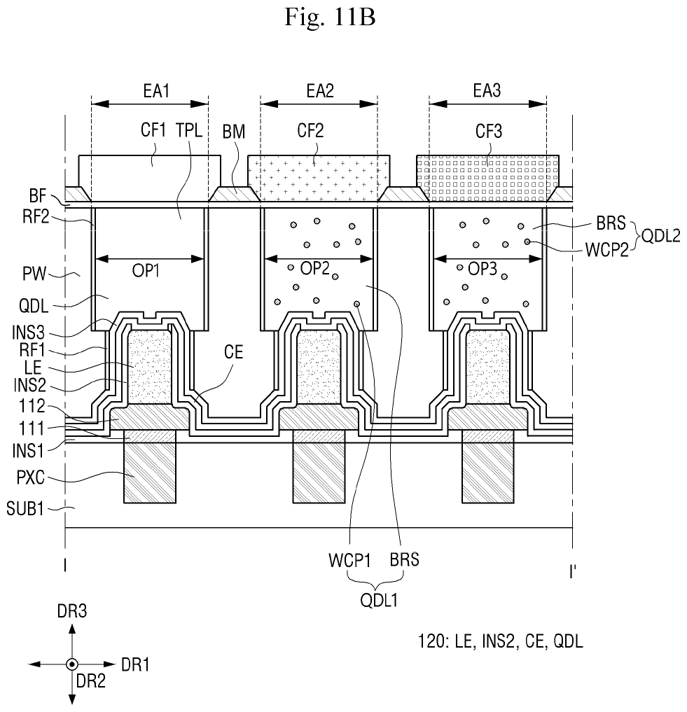

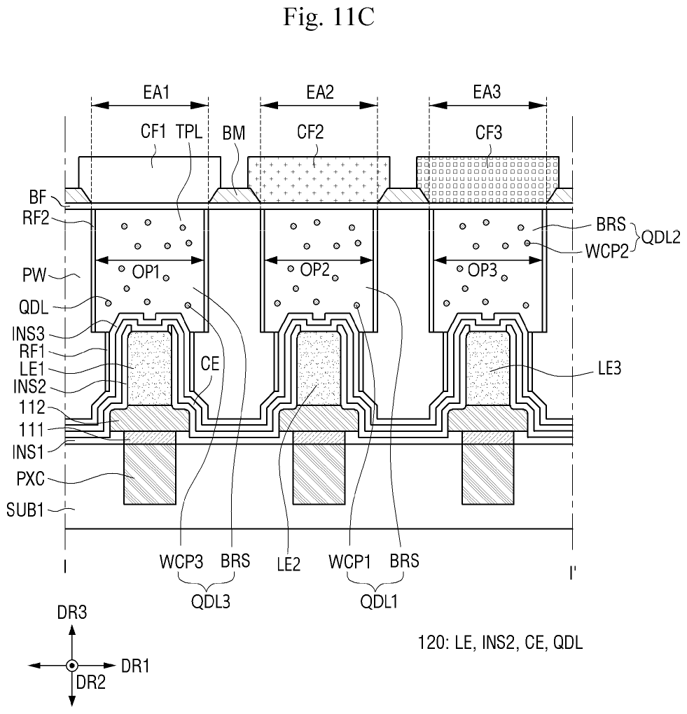

Each of the pixels PX may include a plurality of emission areas (EA1 through EA4). FIG. 1B illustrates that each of the pixels PX includes four emission areas, i.e., the first through fourth emission areas EA1 through EA4, but the present disclosure is not limited thereto. Alternatively, each of the pixels PX may include three emission areas, i.e., first through third emission areas EA1 through EA3, and each of the first through third emission areas EA1 through EA3 may include a light-emitting element LE emitting first light. For example, referring to FIG. 11C, the first through third emission areas EA1 through EA3 may include first through third light-emitting elements LE1 through LE3, respectively, emitting different wavelengths of light.

First emission areas EA1 refer to areas that emit first light. The first emission areas EA1 may emit first light output from light-emitting elements LE as it is. First light may be light in a blue wavelength range. The blue wavelength range may be about 370 nm to about 460 nm, but the present disclosure is not limited thereto.

Second emission areas EA2 refer to areas that emit second light. The second emission areas EA2 may convert some of the first light output from the light-emitting elements LE into second light and may output the second light. Second light may be light in a green wavelength range. The green wavelength range may be about 480 nm to about 560 nm, but the present disclosure is not limited thereto.

Third emission areas EA3 refer to areas that emit third light. The third emission areas EA3 may convert some of the first light output from the light-emitting elements LE into third light and may output the third light. Third light may be light in a red wavelength range. The red wavelength range may be about 600 nm to about 750 nm, but the present disclosure is not limited thereto.

The first emission areas EA1, the second emission areas EA2, and the third emission areas EA3 may be alternately arranged along the first direction DR1. For example, the first emission areas EA1, the second emission areas EA2, and the third emission areas EA3 may be arranged in the order of first, second, and third emission areas EA1, EA2, and EA3 along the first direction DR1.

The first emission areas EA1 may be arranged along the second direction DR2. The second emission areas EA2 may be arranged along the second direction DR2. The third emission areas EA3 may be arranged along the second direction DR2.

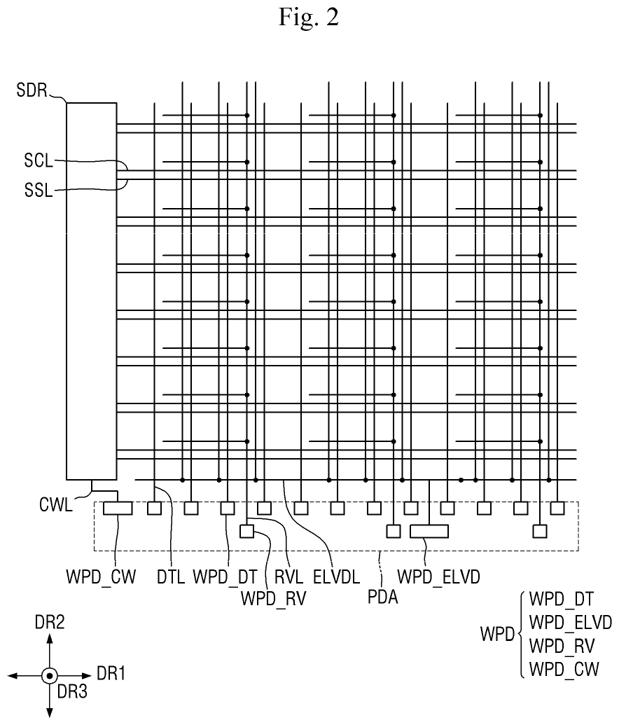

FIG. 2 is a layout view of the circuitry of the display substrate of the display device of FIG. 1A.

Referring to FIG. 2, a plurality of lines are disposed on a first substrate. The plurality of lines may include scan lines SCL, sensing signal lines SSL, data lines DTL, reference voltage lines RVL, and a first power supply line ELVDL.

The scan lines SCL and the sensing signal lines SSL may extend in the first direction DR1. The scan lines SCL and the sensing signal lines SSL may be connected to a scan driving unit SDR. The scan driving unit SDR may include a scan driving circuit. The scan driving unit SDR may be disposed in the non-display area NDA, on one side of the display area DPA, but the present disclosure is not limited thereto. Alternatively, the scan driving unit SDR may be disposed in the non-display area NDA, on both sides of the display area DPA. The scan driving unit SDR may be connected to a signal connecting line CWL, and at least one end of the signal connecting line CWL may form a pad WPD_CW in the non-display area NDA and may be connected to the external device EXD of FIG. 1A.

The data lines DTL and the reference voltage lines RVL may extend in the second direction DR2, which intersects the first direction DR1. The first power supply line ELVDL may include parts extending in the second direction DR2. The first power supply line ELVDL may further include parts extending in the first direction DR1. The first power supply line ELVDL may have a mesh structure, but the present disclosure is not limited thereto.

Wire pads WPD may be disposed at at least one end of each of the data lines DTL, the reference voltage lines RVL, and the first power supply line ELVDL. The wire pads WPD may be disposed in a pad unit PDA of the non-display area NDA. Wire pads WPD_DT (hereinafter, the data wire pads WPD_DT) of the data lines DTL, wire pads WPD_RV (hereinafter, the reference voltage pads WPD_RV) of the reference voltage lines RVL, and a wire pad WPD_ELVD (hereinafter, the first power supply pad WPD_ELVD) of the first power supply line ELVDL May be disposed in the pad unit PDA of the non-display area NDA. Alternatively, the data pads WPD_DT, the reference voltage pads WPD_RV, and the first power supply pad WPD_ELVD may be disposed in different parts of the non-display area NDA. As already mentioned above, the external device EXD of FIG. 1A may be mounted on the wire pads WPD. The external device EXD may be mounted on the wire pads WPD via anisotropic conductive films (ACFs) or ultrasonic bonding.

Each pixel PX on the display substrate includes a pixel driving circuit. The above-described lines may apply driving signals to the pixel driving circuit, passing by or through each pixel PX. The pixel driving circuit may include transistors and a capacitor. The numbers of transistors and capacitors included in the pixel driving circuit may vary. For example, the pixel driving circuit will hereinafter be described as having a “3T1C” structure including three transistors and one capacitor, but the present disclosure is not limited thereto. Alternatively, various other structures such as a “2T1C”, “7T1C”, or “6T1C” structure may also be applicable to the pixel driving circuit.

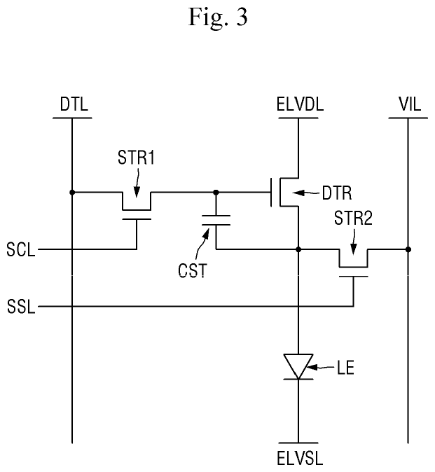

FIG. 3 is an equivalent circuit diagram of a pixel of the display device of FIG. 1A.

Referring to FIG. 3, a pixel PX includes a light-emitting element LE, three transistors, i.e., a driving transistor DTR, a first transistor STR1, and a second transistor STR2, and one capacitor CST.

The light-emitting element LE emits light in accordance with a current applied thereto through the driving transistor DTR. The light-emitting element LE may be implemented as an inorganic light-emitting diode (LED), an OLED, a microLED, or a nanoLED.

A first electrode (or an anode) of the light-emitting element LE may be connected to a source electrode of the driving transistor DTR, a second electrode (or a cathode) of the light-emitting element LE may be connected to a second power supply line ELVSL, to which a low-potential voltage (or a second power supply voltage) is supplied. The second power supply voltage is lower than a high-potential voltage (or a first power supply voltage) supplied to the first power supply line ELVDL.

The driving transistor DTR controls a current flowing from the first power supply line ELVDL into the light-emitting element LE, in accordance with the difference in voltage between a gate electrode and the source electrode of the driving transistor DTR. The gate electrode of the driving transistor DTR may be connected to a first electrode of the first transistor STR1, the source electrode of the driving transistor DTR may be connected to the first electrode of the light-emitting element LE, and a drain electrode of the driving transistor DTR may be connected to the first power supply line ELVDL, to which the first power supply voltage is supplied.

The first transistor STR1 is turned on by a scan signal from a scan line SCL to connect a data line DTL and the gate electrode of the driving transistor DTR. The gate electrode of the first transistor STR1 may be connected to the scan line SCL, the first electrode of the first transistor STR1 may be connected to the gate electrode of the driving transistor DTR, and a second electrode of the first transistor STR1 may be connected to a data line DTL.

The second transistor STR2 is turned on by a sensing signal from a sensing signal line SSL to connect an initialization voltage line VIL and the source electrode of the driving transistor DTR. The gate electrode of the second transistor STR2 may be connected to the sensing signal line SSL, a first electrode of the second transistor STR2 may be connected to the initialization voltage line VIL, and a second electrode of the second transistor STR2 may be connected to the source electrode of the driving transistor DTR.

The first electrodes of the first and second transistors STR1 and STR2 may be source electrodes, and the second electrodes of the first and second transistors STR1 and STR2 may be drain electrodes. Alternatively, the first electrodes of the first and second transistors STR1 and STR2 may be drain electrodes, and the second electrodes of the first and second transistors STR1 and STR2 may be source electrodes.

The capacitor CST is formed between the gate and source electrodes of the driving transistor DTR. The capacitor CST stores a differential voltage corresponding to the difference in voltage between the gate and source electrodes of the driving transistor DTR.

The driving transistor DTR and the first and second transistors STR1 and STR2 may be formed as thin-film transistors (TFTs). FIG. 3 illustrates that the driving transistor DTR and the first and second transistors STR1 and STR2 are N-type metal-oxide semiconductor field-effect transistors (MOSFETs), but the present disclosure is not limited thereto. Alternatively, the driving transistor DTR and the first and second transistors STR1 and STR2 may be P-type MOSFETs. Yet alternatively, some of the driving transistor DTR and the first and second transistors STR1 and STR2 may be P-type MOSFETs, and the other transistors may be N-type MOSFETs.

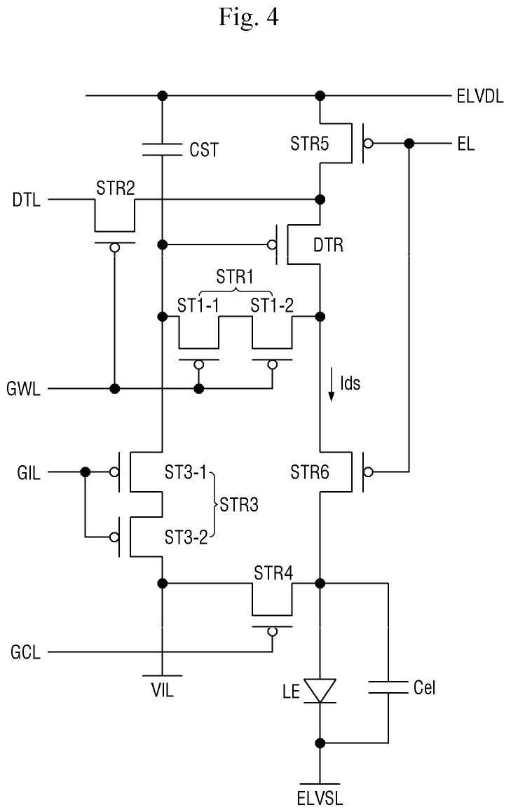

FIG. 4 is an equivalent circuit diagram of a pixel of a display device according to another embodiment of the present disclosure.

Referring to FIG. 4, a first electrode of a light-emitting element LE may be connected to a first electrode of a fourth transistor STR4 and a second electrode of a sixth transistor STR6, and a second electrode of the light-emitting element LE may be connected to a second power supply line ELVSL. A parasitic capacitor Cel may be formed between the first and second electrodes of the light-emitting element LE.

A pixel PX includes a driving transistor DTR, switching elements, and a capacitor CST. The switching elements include a first transistor STR1, a second transistor STR2, a third transistor STR3, the fourth transistor STR4, a fifth transistor STR5, and the sixth transistor STR6.

The driving transistor DTR includes a gate electrode, a first electrode, and a second electrode. The driving transistor DTR controls a drain-source current Ids (hereinafter, the driving current Ids) flowing between the first and second electrodes thereof.

The capacitor CST is formed between the gate electrode of the driving transistor DTR and a first power supply line ELVDL. A first electrode of the capacitor CST may be connected to the gate electrode of the driving transistor DTR, and a second electrode of the capacitor CST may be connected to the first power supply line ELVDL.

If the first electrodes of the first through sixth transistors STR1 through STR6 and the first electrode of the driving transistor DTR are source electrodes, the second electrodes of the first through sixth transistors STR1 through STR6 and the second electrode of the driving transistor DTR may be drain electrodes. Alternatively, if the first electrodes of the first through sixth transistors STR1 through STR6 and the first electrode of the driving transistor DTR are drain electrodes, the second electrodes of the first through sixth transistors STR1 through STR6 and the second electrode of the driving transistor DTR may be source electrodes.

Active layers of the first through sixth transistors STR1 through STR6 and an active layer of the driving transistor DTR may be formed of one or more selected from among polysilicon, amorphous silicon, and/or an oxide semiconductor. For example, the active layers of the first through sixth transistors STR1 through STR6 and the active layer of the driving transistor DTR may be formed of polysilicon by a low-temperature polysilicon (LTPS) process.

FIG. 4 illustrates that the first through sixth transistors STR1 through STR6 and the driving transistor DTR are formed as P-type MOSFETs, but the present disclosure is not limited thereto. Alternatively, the first through sixth transistors STR1 through STR6 and the driving transistor DTR may be formed as N-type MOSFETs.

A first power supply voltage from a first power supply line ELVDL, a second power supply voltage from the second power supply line ELVSL, and a third power supply voltage from a third power supply line VIL may be set in consideration of the characteristics of the driving transistor DTR and the characteristics of the light-emitting element LE.

For example, the first transistor STR1 may be connected between the gate electrode and the second electrode of the driving transistor DTR, and the gate electrode of the first transistor STR1 may be connected to a write scan line GWL. The first transistor may include a first first transistor ST1-1 and a second first transistor ST1-2.

For example, the second transistor STR2 may be connected between the data line DTL and the first electrode of the driving transistor DTR, and the gate electrode of the second transistor STR2 may be connected to the write scan line GWL.

For example, the third transistor STR3 may be connected between the gate electrode of the driving transistor DTR and the third power supply line VIL (e.g., an initialization voltage line), and the gate electrode of the third transistor STR3 may be connected to an initialization scan line GIL. The third transistor may include a first third transistor ST3-1 and a second third transistor ST3-2.

For example, the fourth transistor STR4 may be connected between the third power supply line VIL (e.g., an initialization voltage line) and the light emitting element LE and the second electrode of the sixth transistor STR6, and the gate electrode of the fourth transistor STR4 may be connected to the control scan line GCL.

For example, the fifth transistor STR5 may be connected between the first power supply line ELVDL and the first electrode of the driving transistor DTR, and the gate electrode of the fifth transistor STR5 may be connected to an emission control line EL.

For example, the sixth transistor STR6 may be connected between the second electrode of the driving transistor DTR and the light emitting element LE, and the gate electrode of the sixth transistor STR6 may be connected to the emission control line EL.

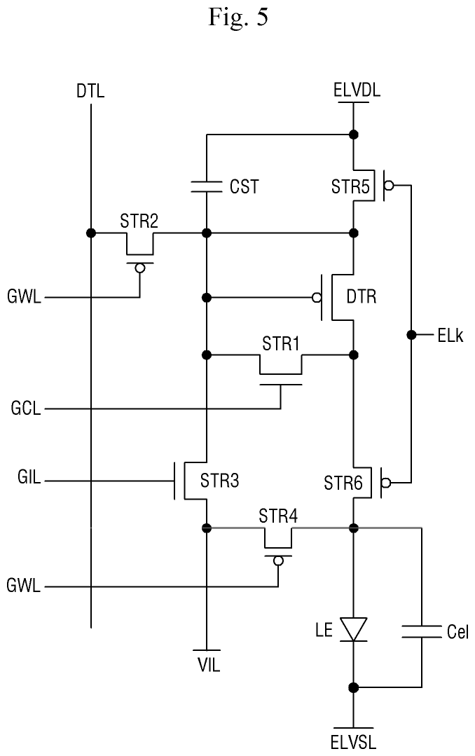

FIG. 5 is an equivalent circuit diagram of a pixel of a display device according to one or more embodiments of the present disclosure.

The embodiment of FIG. 5 differs from the embodiment of FIG. 4 in that a driving transistor DTR and the second, fourth, fifth, and sixth transistors STR2, STR4, STR5, and STR6 are formed as P-type MOSFETs and first and third transistors STR1 and STR3 are formed as N-type MOSFETs.

Referring to FIG. 5, active layers of P-type MOSFETs, i.e., an active layer of the driving transistor DTR and active layers of the second, fourth, fifth, and sixth transistors STR2, STR4, STR5, and STR6, may be formed of polysilicon, and active layers of N-type MOSFETs, i.e., active layers of the first and third transistors STR1 and STR3, may be formed of an oxide semiconductor.

The embodiment of FIG. 5 also differs from the embodiment of FIG. 4 in that gate electrodes of the second and fourth transistors STR2 and STR4 are connected to a write scan line GWL and a gate electrode of the first transistor ST1 is connected to a control scan line GCL. As the first and third transistors STR1 and STR3 are formed as N-type MOSFETs, a scan signal having a gate-high voltage may be applied to the control scan line GCL and an initialization scan line GIL. On the contrary, as the second, fourth, fifth, and sixth transistors STR2, STR4, STR5, and STR6 are formed as P-type MOSFETs, a scan signal having a gate-low voltage may be applied to the write scan line GWL and an emission line ELk.

The present disclosure is not limited to the equivalent circuit diagrams of FIGS. 3 through 5, and various other circuit configurations that are available to one of ordinary skill in the art, to which the present disclosure pertains, may also be employed.

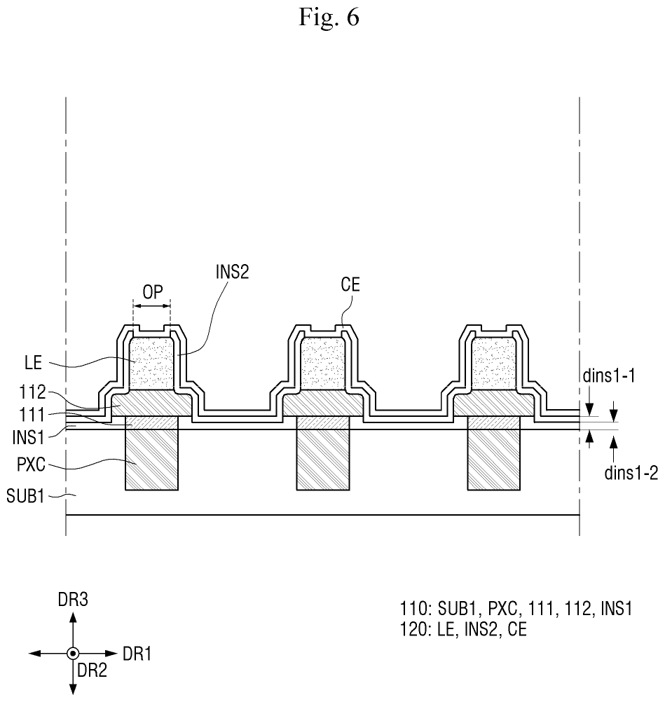

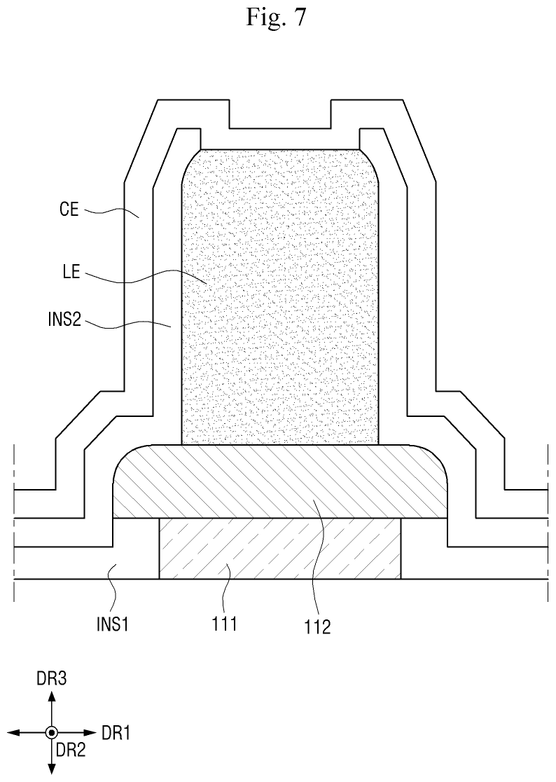

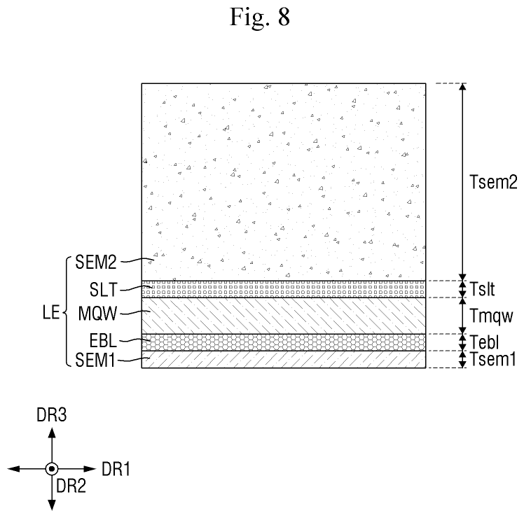

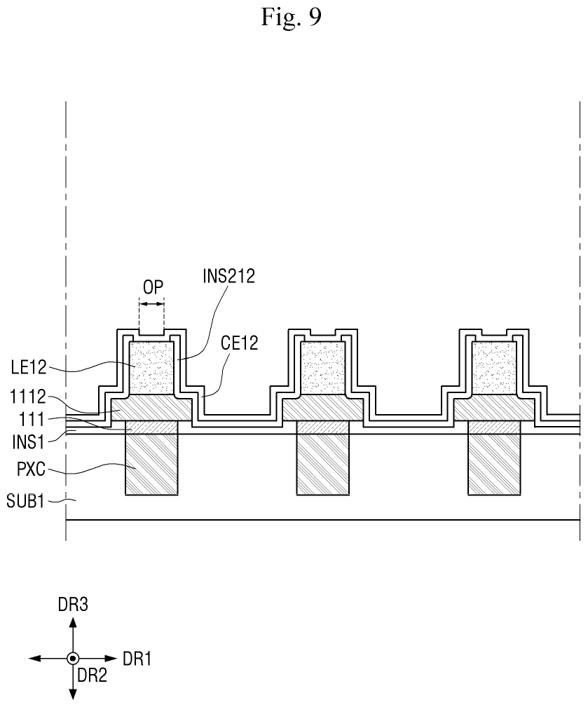

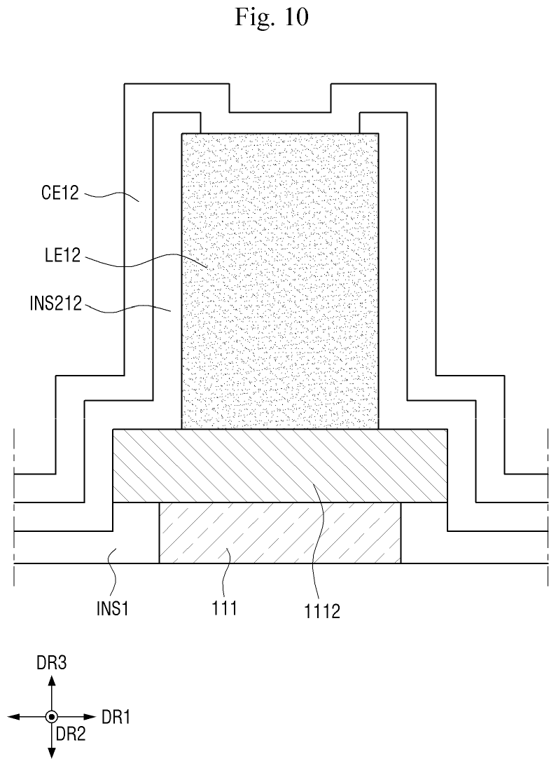

FIG. 6 is a cross-sectional view of part of the display device of FIG. 1A. FIG. 7 is an enlarged cross-sectional view illustrating a pixel electrode and a light-emitting element according to one or more embodiments of the present disclosure. FIG. 8 is an enlarged cross-sectional view of a light-emitting element of FIG. 6. FIG. 9 is a cross-sectional view of a light-emitting elements of FIG. 6. FIG. 10 is an enlarged cross-sectional view of a pixel electrode and a light-emitting element of FIG. 9. FIG. 11A is a cross-sectional view, taken along the line I-I′ of FIG. 1B, of a display panel according to one or more embodiments of the present disclosure.

Referring to FIGS. 6 through 8, the display panel 100 may include a semiconductor circuit substrate 110 and a light-emitting element layer 120.

The semiconductor circuit substrate 110 may include a first substrate SUB1, a plurality of pixel circuit units PXC, a plurality of pixel electrodes 111, connecting electrodes 112, and a first insulating layer INS1.

The first substrate SUB1 may be a silicon wafer substrate. The first substrate SUB1 may be formed of monocrystalline silicon.

The pixel circuit units PXC may be disposed in the first substrate SUB1. The pixel circuit units PXC may include complementary metal-oxide semiconductor (CMOS) circuits formed by a semiconductor process. Each of the pixel circuit units PXC may include at least one transistor formed by a semiconductor process. Each of the pixel circuit units PXC may further include at least one capacitor formed by a semiconductor process.

The pixel circuit units PXC may be disposed in the display area DPA. The pixel circuit units PXC may be connected to pixel electrodes 111. That is, the pixel circuit units PXC may be connected to the pixel electrodes 111 to correspond one-to-one to the pixel electrodes 111. The pixel circuit units PXC may apply pixel voltages or anode voltages to the pixel electrodes 111.

The pixel electrodes 111 may be disposed on the pixel circuit units PXC. The pixel electrodes 111 may be electrodes exposed from the pixel circuit units PXC. That is, the pixel electrodes 111 may be exposed from the top surfaces of the pixel circuit units PXC. The pixel electrodes 111 may be integrally formed with the pixel circuit units PXC. The pixel electrodes 111 may receive pixel voltages or anode voltages from the pixel circuit units PXC. The pixel electrodes 111 may include one or more selected from among tungsten (W), copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), and/or a mixture thereof. The pixel electrodes 111 may have a multilayer structure in which two or more metal layers are stacked. For example, the pixel electrodes 111 may have a structure in which a Cu layer is stacked on a Ti layer, but the present disclosure is not limited thereto.

The first insulating layer INS1 may be disposed on parts of the first substrate SUB1 where the pixel electrodes 111 are not disposed. The first insulating layer INS1 may be disposed between the pixel electrodes 111 and may be formed to have a stepped structure. The first insulating layer INS1 may be formed to have a first thickness dins1-1 in areas overlapping with the connecting electrodes 112 and a second thickness dins1-2 in areas not overlapping with the connecting electrodes 112. The first thickness dins1-1 may be greater than the second thickness dins1-2. That is, the first insulating layer INS1 may be formed to be thicker in the areas overlapping with the connecting electrodes 112 than in the areas not overlapping with the connecting electrodes 112.

The first insulating layer INS1 may be formed as an inorganic film such as a silicon oxide (SiO₂) film, an aluminum oxide (Al₂O₃) film, and/or a hafnium oxide (HfOₓ) film.

The connecting electrodes 112 may be disposed on the pixel electrodes 111. The connecting electrodes 112 may function as bonding metals for bonding the pixel electrodes 111 and the light-emitting elements LE during the fabrication of the display device 10. The connecting electrodes 112 may include a nonvolatile element. The nonvolatile element may be, for example, at least one Group XI element such as Au, Cu, Ag, and/or roentgenium (Rg). The connecting electrodes 112 may be formed to have rounded upper corners.

The light-emitting element layer 120 may include light-emitting elements LE, a second insulating layer INS2, and a common electrode CE.

The light-emitting elements LE may be disposed on the connecting electrodes 112. The light-emitting elements LE may be disposed to overlap with the pixel electrodes 111. The light-emitting elements LE may be vertical LEDs extending in the third direction DR3. That is, the length, in the third direction DR3, of the light-emitting elements LE may be greater than the length, in a horizontal direction, of the light-emitting elements LE. Here, the length, in the horizontal direction, of the light-emitting elements LE may refer to the length, in the first or second direction DR1 or DR2, of the light-emitting elements LE. For example, the length, in the third direction DR3, of the light-emitting elements LE may be about 1 μm to about 5 μm. The light-emitting elements LE may be formed to have rounded upper corners.

In a case where the light-emitting elements LE and the connecting electrodes 112 are formed to have rounded upper corners, the second insulating layer INS2 and the common electrode CE may also be formed to have rounded upper corners.

On the other hand, as illustrated in FIGS. 9 and 10, light-emitting elements LE12 and connecting electrodes 1112 may be formed to have upper corners that are not rounded, but right-angled. In this case, the second insulating layer INS212 and the common electrode CE12 may also be formed to have right-angled upper corners.

The shape of the upper corners of each of the second insulating layer INS212 and the common electrode CE12 may vary depending on the shape of the upper corners of each of the light-emitting elements LE12 and the connecting electrodes 1112.

Referring again to FIGS. 6 through 8, the light-emitting elements LE may be microLEDs or nanoLEDs. Each of the light-emitting elements LE may include a first semiconductor layer SEM1, an electron blocking layer EBL, an active layer MQW, a superlattice layer SLT and a second semiconductor layer SEM2, as illustrated in FIG. 8. The first semiconductor layer SEM1, the electron blocking layer EBL, the active layer MQW, the superlattice layer SLT, and the second semiconductor layer SEM2 may be sequentially stacked in the third direction DR3, as illustrated in FIG. 8.

The light-emitting elements LE may have a cylindrical shape that extends longer latitudinally than longitudinally, a disk shape, or a rod shape, but the present disclosure is not limited thereto. Alternatively, the light-emitting elements LE may have a wire shape, a tube shape, a polygonal prism shape (such as a cube shape, a cuboid shape, or a hexagonal prism shape), or various other shapes such as a shape extending in one direction with outer sides partially inclined.

The first semiconductor layer SEM1 may be disposed on one of the connecting electrodes 112. The first semiconductor layer SEM1 may be doped with a dopant of a first conductivity type such as magnesium (Mg), zinc (Zn), Ca, selenium (Se), and/or barium (Ba). For example, the first semiconductor layer SEM1 may be p-GaN doped with Mg, which is a p-type dopant. A thickness Tsem1 of the first semiconductor layer SEM1 may be about 30 nm to about 200 nm.

The electron blocking layer EBL may be disposed on the first semiconductor layer SEM1. The electron blocking layer EBL may be a layer suppressing or preventing the flow of too many electrons into the active layer MQW. For example, the electron blocking layer EBL may be p-AlGaN doped with Mg, which is a p-type dopant. A thickness Tebl of the electron blocking layer EBL may be about 10 nm to about 50 nm. In one or more embodiments, the electron blocking layer EBL may not be provided.

The active layer MQW may be disposed on the electron blocking layer EBL. The active layer MQW may emit light through the combination of electron-hole pairs in accordance with electric signals applied thereto from the first and second semiconductor layers SEM1 and SEM2. The active layer MQW may emit first light having a central wavelength band of 450 nm to 495 nm, i.e., blue-wavelength light, but the present disclosure is not limited thereto.

The active layer MQW may include a material having a single- or multi-quantum well structure. In a case where the active layer MQW includes a material having a multi-quantum well structure, the active layer MQW may have a structure in which a plurality of well layers and a plurality of barrier layers are alternately stacked. The well layers may be formed of, but is not limited to, InGaN, and the barrier layers may be formed of, but is not limited to, GaN or AlGaN. The thickness of the well layers may be about 1 nm to about 4 nm, and the thickness of the barrier layers may be about 3 nm to about 10 nm.

Alternatively, the active layer MQW may have a structure in which semiconductor materials having a large bandgap energy and semiconductor materials having a small bandgap energy are alternately stacked or may include a Group III semiconductor material or a Group V semiconductor material depending on the wavelength band of light to be emitted by the active layer MQW. Light emitted by the active layer MQW is not limited to the first light, and in one or more embodiments, the active layer MQW may emit second light (or green-wavelength light) or third light (or red-wavelength light).

The superlattice layer SLT may be disposed on the active layer MQW. The superlattice layer SLT may be a layer for alleviating the stress between the second semiconductor layer SEM2 and the active layer MQW. For example, the superlattice layer SLT may be formed of InGaN and/or GaN. A thickness Tslt of the superlattice layer SLT may be about 50 nm to about 200 nm. In one or more embodiments, the superlattice layer SLT may not be provided.

The second semiconductor layer SEM2 may be disposed on the superlattice layer SLT. The second semiconductor layer SEM2 may be doped with a dopant of a second conductivity type such as silicon (Si), germanium (Ge), and/or Sn. For example, the second semiconductor layer SEM2 may be n-GaN doped with Si. A thickness Tsem2 of the second semiconductor layer SEM2 may be about 500 nm to about 1 μm.

The second insulating layer INS2 may be disposed on the side surfaces of each of the light-emitting elements LE and parts of the top surface and the side surfaces of each of the connecting electrodes 112 that do not overlap with the light-emitting elements LE. The second insulating layer INS2 may be disposed on parts of the first insulating layer INS1 where the light-emitting elements LE are not disposed. The second insulating layer INS2 may be formed to cover all parts of the first insulating layer INS1 where the light-emitting elements LE are disposed and may include openings OP above the light-emitting elements LE.

The second insulating layer INS2 may be formed as an inorganic film such as a SiO₂ film, an Al₂O₃ film, and/or a HfOₓ film, but the present disclosure is not limited thereto.

As the common electrode CE is disposed on the entire first substrate SUB1 and a common voltage is applied to the common electrode CE, the common electrode CE may include a low-resistance material. The common electrode CE may be disposed on the top surfaces of the light-emitting elements LE and the top surface of the second insulating layer INS2. The common electrode CE may be in contact with the light-emitting elements LE through the openings OP of the second insulating layer INS2.

The common electrode CE may be formed to be thin enough to properly transmit light therethrough. The common electrode CE may include a transparent conductive material. For example, the common electrode CE may include a transparent conductive oxide (TCO) such as indium tin oxide (ITO) or indium zinc oxide (IZO). The thickness of the common electrode CE may be about 10 Å to about 200 Å, but the present disclosure is not limited thereto.

A third insulating layer INS3 may be disposed on the common electrode. The third insulating layer INS3 may be formed as an inorganic film such as a SiO₂ film, an Al₂O₃ film, and/or a HfOₓ film, but the present disclosure is not limited thereto.

Referring to FIG. 11A, a display panel 100 may further include a semiconductor circuit substrate 110, a light-emitting element layer 120, a wavelength conversion layer QDL, and a color filter layer CFL.

The semiconductor circuit substrate 110 and the light-emitting element layer 120 are the same as their respective counterparts of FIGS. 6 through 8, and thus, detailed descriptions thereof will be omitted.

The light-emitting element layer 120 may include light-emitting elements LE, a second insulating layer INS2, a common electrode CE, and the wavelength conversion layer QDL.

Referring to FIG. 2 and FIG. 11A, a pixel PX may include a plurality of emission areas (EA1 through EA3), i.e., first through third emission areas EA1 through EA3. Each of the first through third emission areas EA1 through EA3 may include a light-emitting element LE, which emits first light.

The first emission area EA1 refers to an area that emits first light. The first emission area EA1 may output first light output from a light-emitting element LE as it is. The first light may be light in a blue wavelength range. The blue wavelength range may be about 370 nm to 460 nm, but the present disclosure is not limited thereto.

The first emission area EA1 may include a light-emitting element LE, a light-transmitting layer TPL, and a first color filter CF1. The light-emitting element LE, the light-transmitting layer TPL, and the first color filter CF1 may overlap with one another in the third direction DR3. The light-transmitting layer TPL may transmit first light output from the light-emitting element LE therethrough as it is, and the first color filter CF1 may also transmit first light therethrough. Accordingly, the first emission area EA1 may emit first light.

The second emission area EA2 may include a light-emitting element LE, a wavelength conversion layer QDL, and a second color filter CF2. The light-emitting element LE, the wavelength conversion layer QDL, and the second color filter CF2 may overlap with one another in the third direction DR3. The wavelength conversion layer QDL may convert some of first light output from the light-emitting element LE into fourth light and may output the fourth light. The fourth light may include both a green wavelength range and a red wavelength range. That is, the fourth light may be the mixture of second light and third light. The second color filter CF2 may transmit second light therethrough. Accordingly, the second emission area EA2 may emit second light.

The third emission area EA3 may include a light-emitting element LE, a wavelength conversion layer QDL, and a third color filter CF3. The light-emitting element LE, the wavelength conversion layer QDL, and the third color filter CF3 may overlap with one another in the third direction DR3. The wavelength conversion layer QDL may convert some of first light output from the light-emitting element LE into fourth light and may output the third light. The third color filter CF3 may transmit third light therethrough. Accordingly, the third emission area EA3 may emit third light.

The light-transmitting layer TPL and the wavelength conversion layers QDL may have a larger area than the light-emitting elements LE. The first through third color filters CF1 through CF3 may have a larger area than the light-emitting elements LE. The first through third color filters CF1 through CF3 may also have a larger area than the light-transmitting layer TPL and the wavelength conversion layers QDL.

The light-emitting element LE of the first emission area EA1 may be completely covered by the light-transmitting layer TPL, and the light-transmitting layer TPL may be completely covered by the first color filter CF1. The light-emitting element LE of the second emission area EA2 may be completely covered by the wavelength conversion layer QDL of the second emission area EA2, and the wavelength conversion layer QDL of the second emission area EA2 may be completely covered by the second color filter CF2. The light-emitting element LE of the third emission area EA3 may be completely covered by the wavelength conversion layer QDL of the third emission area EA3, and the wavelength conversion layer QDL of the third emission area EA3 may be completely covered by the third color filter CF3.

The planar shapes of the light-transmitting layer TPL, the wavelength conversion layers QDL, and the first through third color filters CF1 through CF3 may conform to the planar shape of the light-emitting elements LE. For example, if the light-emitting elements LE have a rectangular planar shape, the light-transmitting layer TPL, the wavelength conversion layers QDL, and the first through third color filters CF1 through CF3 may also have a rectangular planar shape. In another example, if the light-emitting elements LE have a polygonal shape other than a rectangular shape, a circular shape, an elliptical shape, and/or an amorphous shape, the light-transmitting layer TPL, the wavelength conversion layers QDL, and the first through third color filters CF1 through CF3 may also have a polygonal shape other than a rectangular shape, a circular shape, an elliptical shape, and/or an amorphous shape.

Alternatively, the planar shapes of the light-transmitting layer TPL, the wavelength conversion layers QDL, and the first through third color filters CF1 through CF3 may not conform to the planar shape of the light-emitting elements LE. In this case, the planar shapes of the light-transmitting layer TPL, the wavelength conversion layers QDL, and the first through third color filters CF1 through CF3 may differ from the planar shape of the light-emitting elements LE. Also, the planar shapes of the light-transmitting layer TPL and the wavelength conversion layers QDL may differ from the planar shapes of the first through third color filters CF1 through CF3.

The light-transmitting layer TPL may include a light-transmitting organic material. For example, the light-transmitting layer TPL may include an epoxy resin, an acrylic resin, a cardo resin, and/or an imide resin.

The wavelength conversion layers QDL may be disposed to completely cover the light-emitting elements LE in the second and third emission areas EA2 and EA3.

Each of the wavelength conversion layers QDL may include a base resin BRS and wavelength conversion particles WCP. The wavelength conversion particles WCP may convert first light, emitted from the light-emitting elements LE, into yellow-wavelength light. For example, the wavelength conversion particles WCP may convert blue-wavelength light into yellow-wavelength light. The wavelength conversion particles WCP may be quantum dots (QDs), quantum rods, a fluorescent material, and/or a phosphorescent material. The QDs may include Group IV nanocrystals, Group II-VI compound nanocrystals, Group III-V compound nanocrystals, Group IV-VI nanocrystals, and/or a combination thereof.

The QDs may include cores and shells overcoating the cores. For example, the cores may be, but are not limited to, at least one selected from among CdS, CdSe, CdTe, ZnS, ZnSe, ZnTe, GaN, GaP, GaAs, GaSb, AlN, AlP, AlAs, AlSb, InP, InAs, InSb, SiC, Ca, Se, In, P, Fe, Pt, Ni, Co, Al, Ag, Au, Cu, FePt, Fe₂O₃, Fe₃O₄, Si, and Ge. For example, the shells may be, but are not limited to, at least one selected from among ZnS, ZnSe, ZnTe, CdS, CdSe, CdTe, HgS, HgSe, HgTe, AlN, AlP, AlAs, AlSb, GaN, GaP, GaAs, GaSb, GaSe, InN, InP, InAs, InSb, TIN, TIP, TIAs, TISb, PbS, PbSe, and PbTe.

Each of the wavelength conversion layers QDL may further include a scatterer for scattering light emitted from the light-emitting elements LE, in random directions. The scatterer may be particles of a metal oxide or an organic material. Here, the metal oxide may be, for example, titanium oxide (TiO₂), zirconium oxide (ZrO₂), silicon dioxide (SiO₂), aluminum oxide (Al₂O₃), indium oxide (In₂O₃), zinc oxide (ZnO), and/or tin oxide (SnO₂), and the organic material may be, for example, an acrylic resin and/or a urethane resin. The scatterer may have a diameter of several nanometers to dozens of nanometers.

A partition wall PW may be disposed on the common electrode CE in the display area DPA and may define and separate the first through third emission areas EA1 through EA3 and a non-emission area NEA. The partition wall PW may be disposed to extend in the first and second directions DR1 and DR2 and may be formed in a lattice pattern in the entire display area DPA. The partition wall PW may not overlap with the first through third emission areas EA1 through EA3 and may overlap with the non-emission area NEA in the third direction DR3.

The partition wall PW may include a plurality of openings (OP1 through OP3), which define the emission areas (EA1 through EA3). The openings (OP1 through OP3) may include a first opening OP1, which overlaps with the first emission area EA1, a second opening OP2, which overlaps with the second emission area EA2, and a third opening OP3, which overlaps with the third emission area EA3. The openings (OP1 through OP3) may correspond to the emission areas (EA1 through EA3). That is, the first through third openings OP1 through OP3 may correspond to the first through third emission areas EA1 through EA3, respectively. The light-transmitting layer TPL and the wavelength conversion layers QDL of the first to third emission areas may be disposed in the plurality of openings (OP1 through OP3).

The partition wall PW may provide space in which to form the wavelength conversion layers QDL. To this end, the partition wall PW may be formed to have a suitable thickness (e.g., a predetermined thickness) of, for example, 1 μm to 10 μm. The partition wall PW may include an organic insulating material to have a suitable thickness (e.g., a predetermined thickness). The organic insulating material may include, for example, an epoxy resin, an acrylic resin, a cardo resin, and/or an imide resin.

First reflective layers RF1 may be positioned between the partition wall PW and the third insulating film INS3, which is the outermost insulating film for each of the light-emitting elements LE, and second reflective layers RF2 may be positioned between the partition wall PW and the wavelength conversion layers QDL. The first reflective layers RF1 and the second reflective layers RF2 may overlap with the non-emission area NEAin the third direction DR3. The first reflective layers RF1 and the second reflective layers RF2 may reflect light emitted sideways from the light-emitting elements LE. The first reflective layers RF1 and the second reflective layers RF2 may include a metal material with high reflectance such as aluminum (Al). The first reflective layers RF1 and the second reflective layers RF2 may have a thickness of about 0.1 μm.

A plurality of color filters (CF1 through CF3) may be disposed on the partition wall PW, the light-transmitting layer TPL, and the wavelength conversion layers QDL. The color filters (CF1 through CF3) may be disposed to overlap with the pixel circuit units PXC, the light-transmitting layer TPL, and the wavelength conversion layers QDL. The color filters (CF1 through CF3) may include first through third color filters CF1 through CF3.

The first color filter CF1 may be disposed on the light-transmitting layer TPL of the first emission area EA1. The first color filter CF1 may transmit first light therethrough and absorb or block second light or third light. For example, the first color filter CF1 may transmit blue-wavelength light therethrough and absorb or block green-wavelength light and red-wavelength light. Thus, the first color filter CF1 may transmit first light emitted from the light-emitting element LE of the first emission area EA1 therethrough. That is, the first light emitted from the light-emitting element LE of the first emission area EA1 may not be converted by a particular wavelength conversion layer and may pass through the first color filter CF1 through the light-transmitting layer TPL. Accordingly, the first emission area EA1 may emit first light.

The second color filter CF2 may be disposed on the wavelength conversion layer QDL of the second emission area EA2. The second color filter CF2 may transmit second light therethrough and absorb or block first light and third light. For example, the second color filter CF2 may transmit green-wavelength light therethrough and absorb or block blue-wavelength light and red-wavelength light. Thus, the second color filter CF2 may absorb or block first light not converted by the wavelength conversion layer QDL of the second emission area EA2, from among first light emitted from the light-emitting element LE of the second emission area EA2. The second color filter CF2 may transmit second light, which corresponds to green-wavelength light, from among fourth light obtained by the wavelength conversion layer QDL of the second emission area EA2, and may absorb or block third light, which corresponds to blue-wavelength light. Accordingly, the second emission area EA2 may emit second light.

The third color filter CF3 may be disposed on the wavelength conversion layer QDL of the third emission area EA3. The third color filter CF3 may transmit third light therethrough and absorb or block first light and second light. For example, the third color filter CF3 may transmit red-wavelength light therethrough and absorb or block blue-wavelength light and green-wavelength light. Thus, the third color filter CF3 may absorb or block first light not converted by the wavelength conversion layer QDL of the third emission area EA3, from among first light emitted from the light-emitting element LE of the third emission area EA3. The third color filter CF3 may transmit third light, which corresponds to red-wavelength light, from among fourth light obtained by the wavelength conversion layer QDL of the third emission area EA3, and may absorb or block second light, which corresponds to green-wavelength light. Accordingly, the third emission area EA3 may emit third light.

A black matrix BM may be disposed between the color filters (CF1 through CF3). For example, the black matrix BM may be disposed between the first and second color filters CF1 and CF2, between the second and third color filters CF2 and CF3, and between the third color filter CF3 and another first color filter CF1 adjacent thereto. The black matrix BM may include an inorganic black pigment such as carbon black or an organic black pigment.

The color filters (CF1 through CF3) may partially overlap with one another. For example, the first color filter CF1 may partially overlap with the second color filter CF2, the second color filter CF2 may partially overlap with the first and/or third color filter CF1 and/or CF3, and the third color filter CF3 may partially overlap with the second color filter CF2 and/or another first color filter CF1. In this case, as the overlapping areas of the color filters (CF1 through CF3) perform the functions of the black matrix BM, the black matrix BM may not be provided.

A light-blocking member BM may be disposed on the partition wall PW. The light-blocking member BM may overlap with the non-emission area NEA and may block the transmission of light. The light-blocking member BM, like the partition wall PW, may substantially have a lattice shape in a plan view. The light-blocking member BM may be disposed to overlap with the partition wall PW, but not with the first through third emission areas.

The light-blocking member BM may include an organic light-blocking material and may be formed by coating and exposing the organic light-blocking material. The light-blocking member BM may include a light-blocking pigment or dye and may be a black matrix. The light-blocking member BM may overlap at least partially with the first through third color filters CF1 through CF3, and the first through third color filters CF1 through CF3 may overlap at least partially with the light-blocking member BM.

In a case where the light-blocking member BM is disposed on the partition wall PW, at least some external light is absorbed by the light-blocking member BM. Thus, the distortion of colors that may be caused by the reflection of external light can be reduced. Also, the light-blocking member BM can prevent light from infiltrating between adjacent emission areas to cause the mixture of colors, and as a result, the color reproducibility of the display device 10 can be further improved.

In one or more embodiments, the color filters (CF1 through CF3) and a buffer layer BF may be disposed below the first through third color filters CF1 through CF3 and the light-blocking member BM. The buffer layer BF may be disposed on the partition wall PW, the light-transmitting layer TPL, and the wavelength conversion layers QDL. In one or more embodiments, a surface of the buffer layer BF, for example, the top surface of the buffer layer BF, may be in contact with the bottom surfaces of the first through third color filters CF1 through CF3 and the bottom surface of the light-blocking member BM. In one or more embodiments, the other surface of the buffer layer BF, for example, the bottom surface of the buffer layer BF, may be in contact with the top surface of the partition wall PW, the top surface of the light-transmitting layer TPL, and the top surfaces of the wavelength conversion layers QDL. The buffer layer BF may include an inorganic insulating material. For example, the buffer layer BF may include one or more selected from among silicon oxide (SiOₓ), silicon nitride (SiNₓ), silicon oxynitride (SiOₓN_{y}), aluminum oxide (AlₓO_{y}), and/or aluminum nitride (AlN), but the present disclosure is not limited thereto. For example, the buffer layer BF may have a width of 0.01 μm to 1 μm, but the present disclosure is not limited thereto.

FIG. 11B is a cross-sectional view, taken along the line I-I′ of FIG. 1B, of a display panel according to one or more embodiments of the present disclosure. The embodiment of FIG. 11B differs from the embodiment of FIG. 11A in that first and second wavelength conversion layers QDL1 and QDL2 are disposed in second and third emission areas EA2 and EA3, respectively. The embodiment of FIG. 11B will hereinafter be described, focusing mainly on the differences with the embodiment of FIG. 11A.

Referring to FIG. 11B, the first wavelength conversion layer QDL1 may be disposed on a third insulating layer INS3, in the second emission area EA2. The first wavelength conversion layer QDL1 may overlap with a light-emitting element LE in a third direction DR3, in the second emission area EA2. The first wavelength conversion layer QDL1 may be disposed to completely cover the light-emitting element LE in the second emission area EA2.

The first wavelength conversion layer QDL1 may include a base resin BRS and first wavelength conversion particles WCP1. The first wavelength conversion particles WCP1 may convert first light emitted from the light-emitting element LE into second light. For example, the first wavelength conversion particles WCP1 may convert blue-wavelength light into green-wavelength light.

The second wavelength conversion layer QDL2 may be disposed on the third insulating layer INS3, in the third emission area EA3. The second wavelength conversion layer QDL2 may overlap with a light-emitting element LE in the third direction DR3, in the third emission area EA3. The second wavelength conversion layer QDL2 may be disposed to completely cover the light-emitting element LE in the third emission area EA3.

The second wavelength conversion layer QDL2 may include a base resin BRS and second wavelength conversion particles WCP2. The second wavelength conversion particles WCP2 may convert first light emitted from the light-emitting element LE of the third emission area EA3 into third light. For example, the second wavelength conversion particles WCP2 may convert blue-wavelength light into red-wavelength light.

Second light obtained by the first wavelength conversion layer QDL1 from first light emitted from the light-emitting element LE of the second emission area EA2 may pass through the second color filter CF2. First light not converted by the first wavelength conversion layer QDL1, from among the first light emitted from the light-emitting element LE of the second emission area EA2, may be absorbed or blocked by the second color filter CF2. Accordingly, the second emission area EA2 may emit second light.

Third light obtained by the second wavelength conversion layer QDL2 from first light emitted from the light-emitting element LE of the third emission area EA3 may pass through the third color filter CF3. First light not converted by the second wavelength conversion layer QDL2, from among the first light emitted from the light-emitting element LE of the third emission area EA3, may be absorbed or blocked by the third color filter CF3. Accordingly, the third emission area EA3 may emit third light.

FIG. 11C is a cross-sectional view, taken along the line I-I′ of FIG. 1B, of a display panel according to one or more embodiments of the present disclosure. The embodiment of FIG. 11C differs from the embodiment of FIG. 11A in that a pixel PX includes first through third light-emitting elements LE1 through LE3 and a third wavelength conversion layer QDL3 is disposed in a first emission area EA1. The embodiment of FIG. 11C will hereinafter be described, focusing mainly on the differences with the embodiment of FIG. 11A.

Referring to FIG. 11C, the first light-emitting element LE1 may emit first light. The first light may be blue-wavelength light. For example, the first light may have a main peak wavelength (B-peak) of about 370 nm to about 460 nm, but the present disclosure is not limited thereto.

The second light-emitting element LE2 may emit second light. The second light may be blue-wavelength light. For example, the second light may have a main peak wavelength (G-peak) of about 480 nm to about 560 nm, but the present disclosure is not limited thereto.

The third light-emitting element LE3 may emit third light. The third light may be red-wavelength light. For example, the third light may have a main peak wavelength (R-peak) of about 600 nm to about 750 nm, but the present disclosure is not limited thereto. The third wavelength conversion layer QDL3 may be disposed on a third insulating layer INS3, in the first emission area EA1.

The first emission area EA1 may include the first light-emitting element LE1, the third wavelength conversion layer QDL3, and a first color filter CF1.

The third wavelength conversion layer QDL3 may overlap with the first light-emitting element LE1 in a third direction DR3, in the first emission area EA1. The third wavelength conversion layer QDL3 may be disposed to completely cover the first light-emitting element LE1 in the first emission area EA1.

The third wavelength conversion layer QDL3 may include a base resin BRS and third wavelength conversion particles WCP3. The third wavelength conversion particles WCP3 may convert light having a particular wavelength into first light, and the first color filter CF1 may transmit the first light therethrough. Accordingly, the first emission area EA1 may emit first light. In this manner, the color purity of first light emitted from the first light-emitting element LE1 through the first color filter CF1 can be improved.

A second emission area EA2 may include the second light-emitting element LE2, a first wavelength conversion layer QDL1, and a second color filter CF2.

The first wavelength conversion layer QDL1 may overlap with the second light-emitting element LE2 in the third direction DR3 in the second emission area EA2. The first wavelength conversion layer QDL1 may be disposed to completely cover the second light-emitting element LE2 in the second emission area EA2.

The first wavelength conversion layer QDL1 may include a base resin BRS and first wavelength conversion particles WCP1. The first wavelength conversion particles WCP1 may convert light having a particular wavelength into second light, and the second color filter CF2 may transmit the second light therethrough. Accordingly, the second emission area EA2 may emit second light. In this manner, the color purity of second light emitted from the second light-emitting element LE2 through the second color filter CF2 can be improved.

A third emission area EA3 may include the third light-emitting element LE3, a second wavelength conversion layer QDL2, and a third color filter CF3.

The second wavelength conversion layer QDL2 may overlap with the third light-emitting element LE3 in the third direction DR3 in the third emission area EA3. The second wavelength conversion layer QDL2 may be disposed to completely cover the third light-emitting element LE3 in the third emission area EA3.

The second wavelength conversion layer QDL2 may include a base resin BRS and second wavelength conversion particles WCP2. The second wavelength conversion particles WCP2 may convert light having a particular wavelength into third light, and the third color filter CF3 may transmit the third light therethrough. Accordingly, the third emission area EA3 may emit third light. In this manner, the color purity of third light emitted from the third light-emitting element LE3 through the third color filter CF3 can be improved.

The fabrication of the display device 10 will hereinafter be described.

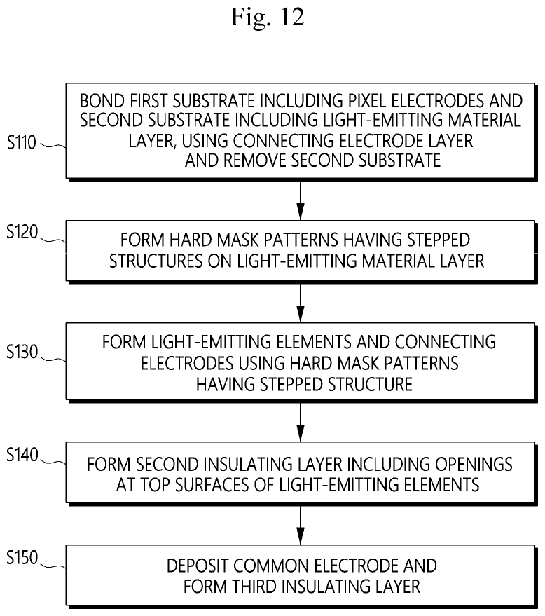

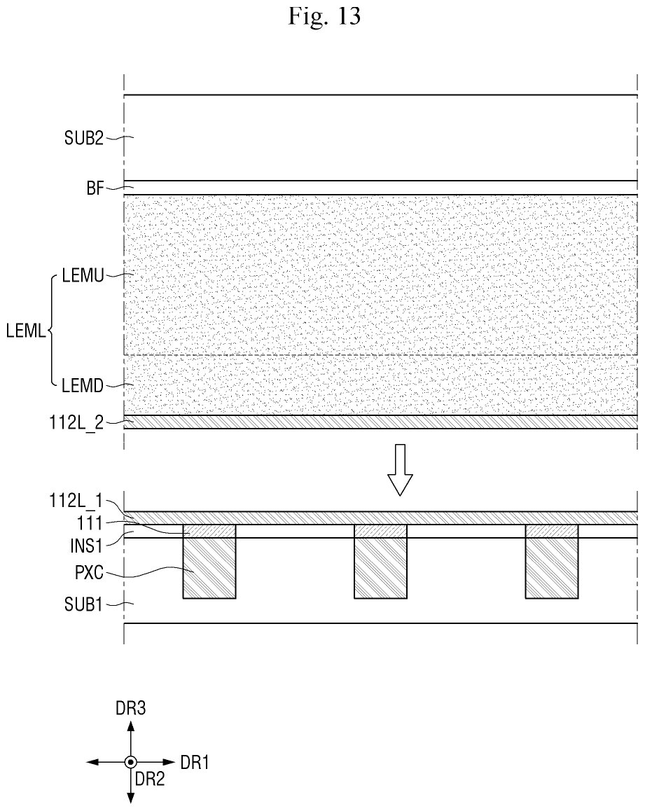

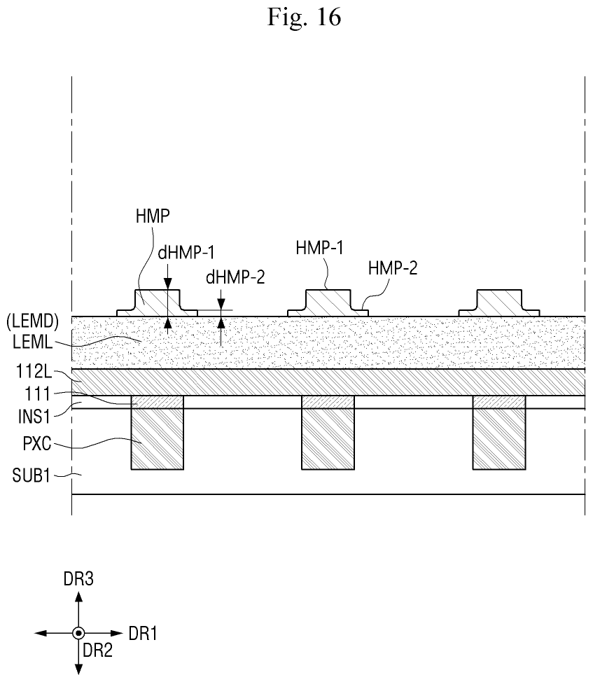

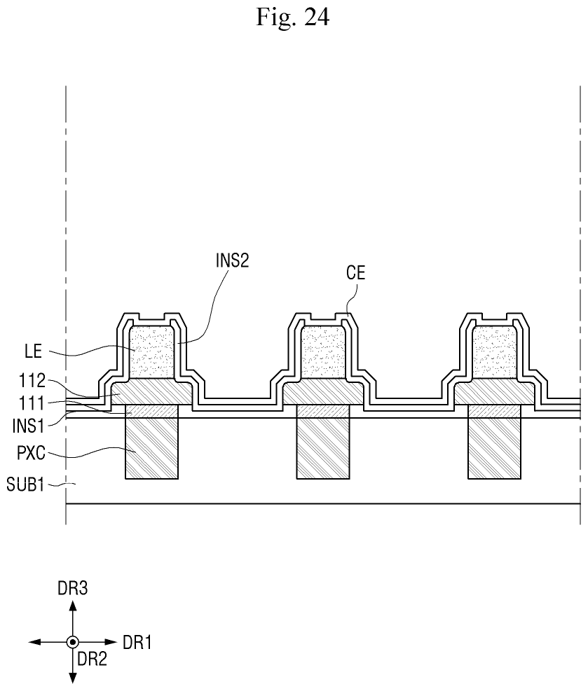

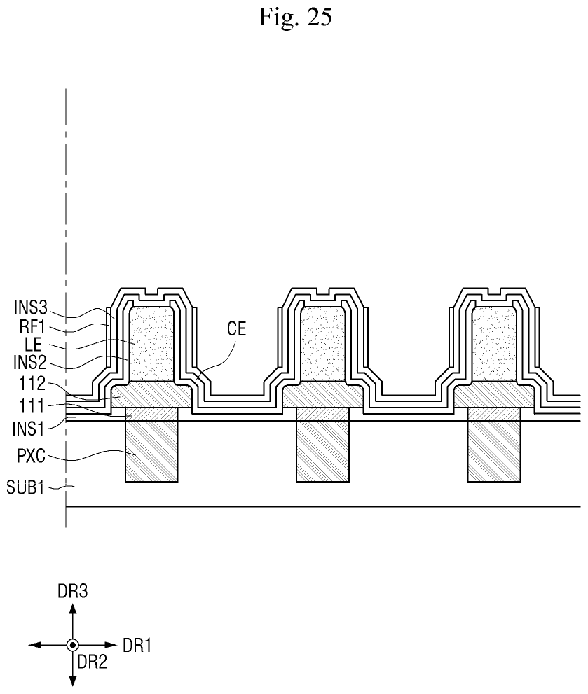

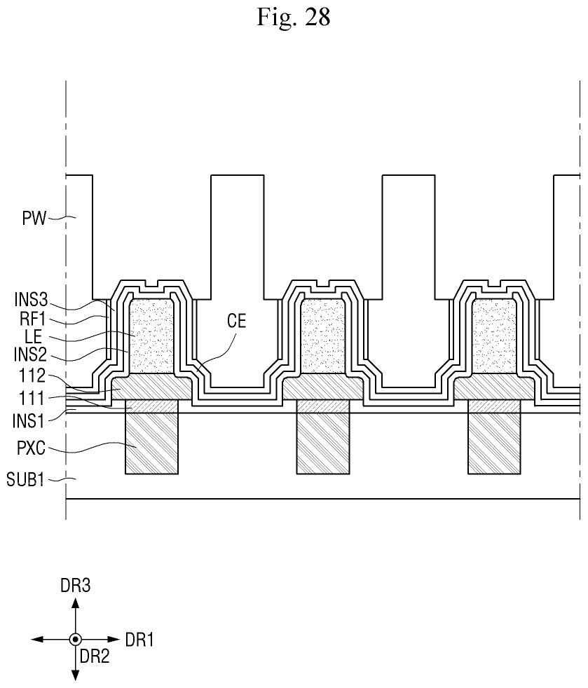

FIG. 12 is a flowchart illustrating a method of fabricating a display device according to one or more embodiments of the present disclosure. FIGS. 13 through 33 are cross-sectional views illustrating the method of FIG. 12.

Referring to FIGS. 12 through 14, a first substrate SUB1 including pixel electrodes 111 and a second substrate SUB2 including a light-emitting material layer LEML are bonded with a connecting electrode layer 112L, and the second substrate SUB2 is removed (S110).

Specifically, referring to FIG. 13, a first insulating layer INS1 is formed on a first substrate SUB1 including pixel circuit units PXC, a first connecting electrode layer 112L_1 is formed on the first insulating layer INS1 and the pixel electrodes 111, and a second connecting electrode layer 112L_2 is formed on a light-emitting material layer LEML of a second substrate SUB2 (S110).

The first insulating layer INS1 is formed on parts of the first substrate SUB1 where the pixel electrodes 111 are not disposed. The top surface of the first insulating layer INS1 may be flatly connected to the top surfaces of the pixel electrodes 111. That is, the difference in height between the top surface of the first substrate SUB1 and the pixel electrodes 111 may be removed by the first insulating layer INS1. The first insulating layer INS1 may be formed as an inorganic film such as a SiO₂ film, an Al₂O₃ film, and/or a HfOₓ film.

Thereafter, the first connecting electrode layer 112L_1 is deposited on the pixel electrodes 111 and the first insulating layer INS1. The first connecting electrode layer 112L_1 may include Au.

A buffer layer BF may be formed on one surface of the second substrate SUB2. The second substrate SUB2 may be a silicon substrate and/or a sapphire substrate. The buffer layer BF may be formed of an inorganic film such as a SiO₂ film, an Al₂O₃ film, and/or a HfOₓ film.

The light-emitting material layer LEML may be disposed on the buffer layer BF. The light-emitting material layer LEML may include first and second semiconductor material layers LEMD and LEMU. The second semiconductor material layer LEMU may be disposed on the buffer layer BF, and the first semiconductor material layer LEMD may be disposed on the second semiconductor material layer LEMU. The thickness of the second semiconductor material layer LEMU may be greater than the thickness of the first semiconductor material layer LEMD.

The first semiconductor material layer LEMD may include a first semiconductor layer SEM1, an electron blocking layer EBL, an active layer MQW, a superlattice layer SLT, and a second semiconductor layer SEM2, as illustrated in FIG. 7. The second semiconductor material layer LEMU may be an undoped semiconductor layer. For example, the second semiconductor material layer LEMU may be an undoped GaN layer.

The second connecting electrode layer 112L_2 may be deposited on the first semiconductor material layer LEMD. The second connecting electrode layer 112L_2 may include Au.

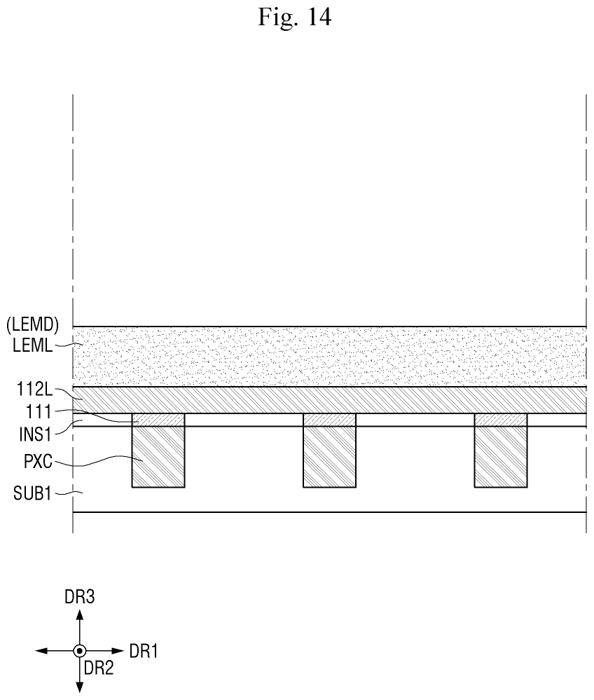

Thereafter, referring to FIG. 14, the first and second connecting electrode layers 112L_1 and 112L_2 are bonded together, and the second substrate SUB2 along with the buffer layer BF and the second semiconductor material layer LEMU are removed.

Specifically, the first connecting electrode layer 112L_1 of the first substrate SUB1 and the second connecting electrode layer 112L_2 of the second substrate SUB2 are placed in contact with each other. Thereafter, the first and second connecting electrode layers 112L_1 and 112L_2 are fusion-bonded at a suitable temperature (e.g., a predetermined temperature), thereby forming a single connecting electrode layer 112L. That is, the connecting electrode layer 112L is disposed between the pixel electrodes 111 of the first substrate SUB1 and the light-emitting material layer LEML of the second substrate SUB2 and function as bonding metals for bonding the pixel electrodes 111 of the first substrate SUB1 and the light-emitting material layer LEML of the second substrate SUB2. A connecting electrode layer may be formed on each of the first and second substrates SUB1 and SUB2, and the first and second substrates SUB1 and SUB2 may be bonded together. Alternatively, the light-emitting material layer LEML may be bonded onto the first substrate SUB1 by forming only one connecting electrode.

After the bonding of the first and second connecting electrode layers 112L_1 and 112L_2, the second substrate SUB2 and the buffer layer BF may be removed by a polishing process such as chemical mechanical polishing (CMP) and/or an etching process. Also, the second semiconductor material layer LEMU of the light-emitting material layer LEML may be removed by a polishing process such as CMP.

Referring to FIGS. 12, 15, and 16, hard mask patterns HMP having a stepped structure are formed on the light-emitting material layer LEML (S120).

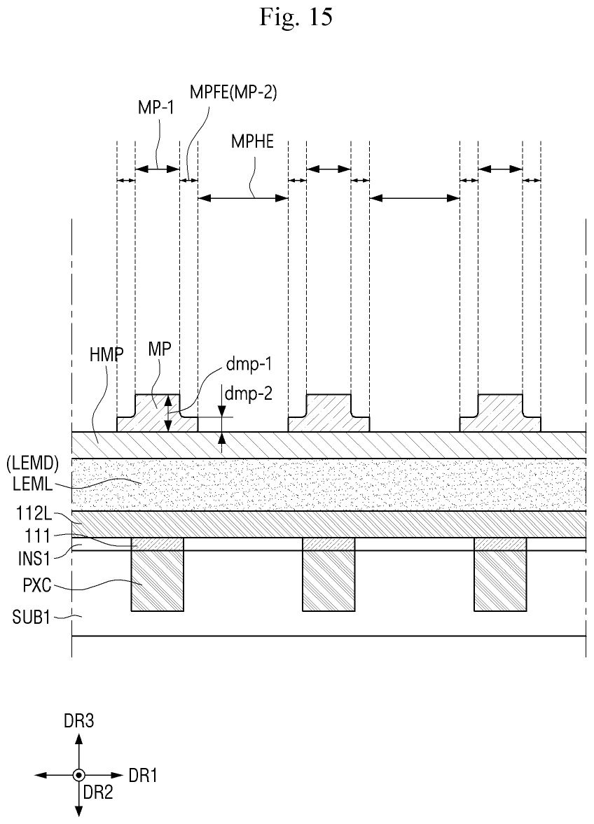

Specifically, referring to FIG. 15, a hard mask material layer HML is formed on the light-emitting material layer LEML, and photoresist mask patterns MP are formed on the hard mask material layer HML. The hard mask material layer HML may be formed of SiOₓ. Accordingly, the hard mask patterns HMP may also be formed of SiOₓ.

The photoresist mask patterns MP may be formed into a stepped structure. The photoresist mask pattern MP may include middle parts MP-1 and edge parts MP-2, which surround the middle parts MP-1.

The middle parts MP-1 of the photoresist mask patterns MP may be disposed in regions where light-emitting elements LE are to be formed. The edge parts MP-2 of the photoresist mask patterns MP may be disposed in regions where connecting electrodes 112 are to be formed.

A thickness dmp-1 of the middle parts MP-1 in the third direction DR3 may be greater than a thickness dmp-2 of the edge parts MP-2 in the third direction DR3. The photoresist mask patterns MP may be formed by transferring photoresist using a halftone mask. Photoresist is a photosensitive material obtained by organically dissolving resin with a photosensitizer. The photoresist mask patterns MP may be formed by full exposure and half exposure. For example, parts of photoresist that are subject to full exposure may receive all irradiated light and may thus react with all thicknesses, and parts of photoresist that are subject to half exposure may receive only some of the irradiated light and may thus react with only particular thicknesses. By performing full exposure and half exposure on photoresist and developing exposed parts of the photoresist, full exposure regions MPFE and half exposure regions MPHE are formed. Due to the half exposure regions MPHE, the photoresist mask patterns MP having a stepped structure are formed.

Thereafter, the hard mask patterns HMP having a stepped structure are formed by etching the photoresist mask patterns MP.

The hard mask patterns HMP may include middle parts HMP-1 and edge parts HMP-2, which surround the middle parts HMP-1, and the shape of the hard mask patterns HMP may conform to the shape of the photoresist mask patterns MP. A thickness dHMP-1 of the middle parts HMP_1 in the third direction DR3 may be greater than a thickness dHMP_2 of the edge parts HMP-2 in the third direction DR3.

Referring to FIGS. 12 and 17 through 20, light-emitting elements LE and connecting electrodes 112 are formed using the hard mask patterns HMP having a stepped structure (S130).

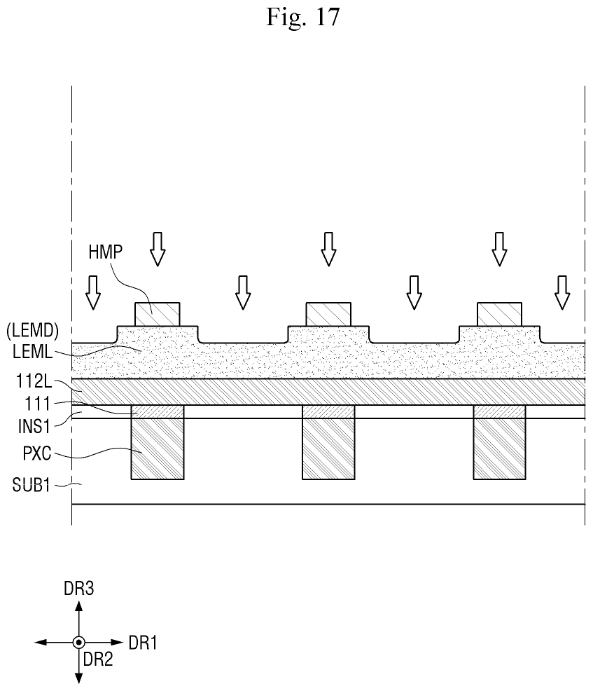

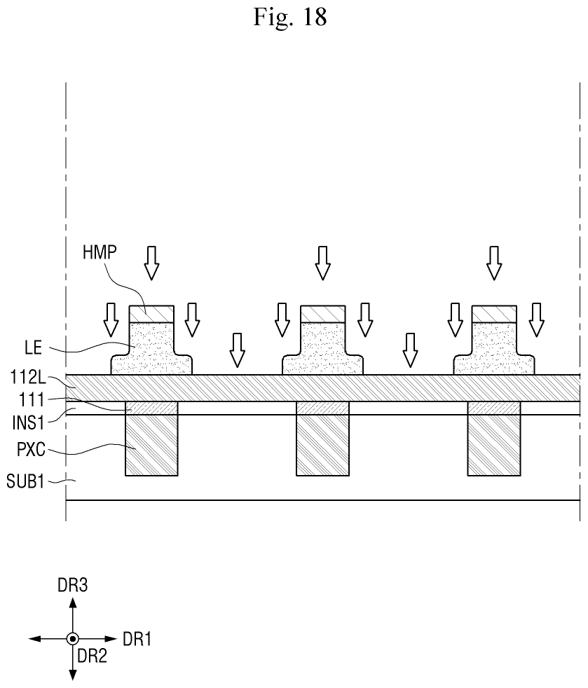

Specifically, referring to FIGS. 17 and 18, the light-emitting material layer LEML is primarily etched until the connecting electrode layer 112L is exposed in the regions where the hard mask patterns HMP are not disposed. As a result, the edge parts HMP_2 of the hard mask patterns HMP are removed, and the thickness of the middle parts HMP-1 of the hard mask patterns HMP generally decreases.

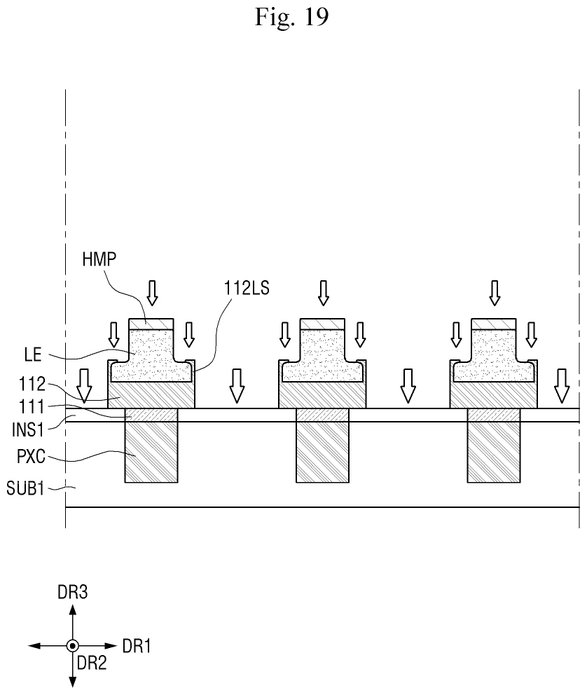

Referring to FIG. 19, the connecting electrodes 112 are formed by performing etching until the first insulating layer INS1 is exposed in the regions where the hard mask patterns HMP are not disposed. A nonvolatile material from the connecting electrode layer 112L may stick to the side surfaces of each of the light-emitting elements LE and may thus form sidewalls 112LS, which are connected to the connecting electrodes 112. If the sidewalls 112LS are not removed, defects may be caused to the light-emitting elements LE.

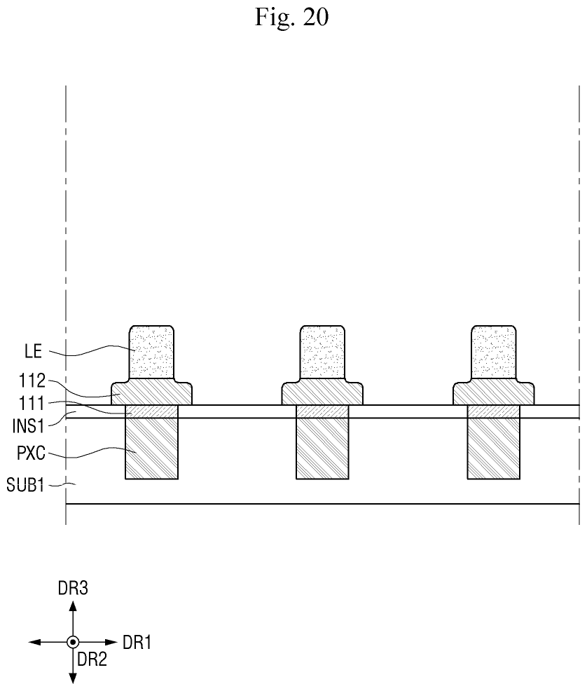

Referring to FIG. 20, etching using the remaining hard mask patterns HMP is continued, thereby forming the light-emitting elements LE and the connecting electrodes 112. As a result, the sidewalls 112LS of FIG. 19 are removed, and vertical light-emitting elements LE are formed. The light-emitting elements LE may be formed to have rounded upper corners. The connecting electrodes 112 may also be formed to have rounded upper corners. The upper corners of each of the light-emitting elements LE and the upper corners of each of the connecting electrodes 112 may have a suitable curvature (e.g., a predetermined curvature). The same etching gas may be used to form both the light-emitting elements LE and the connecting electrodes 112. Thus, etching processes for forming the light-emitting elements LE and the connecting electrodes 112 may be performed one after another in the same chamber.

Parts of the first insulating layer INS1 where the connecting electrodes 112 and the light-emitting elements LE are not disposed are etched, thereby forming a stepped structure. As a result, the first insulating layer INS1 may be thinner in the regions where the connecting electrodes 112 and the light-emitting elements LE are not disposed than in the regions where the connecting electrodes 112 and the light-emitting elements LE are disposed.

Referring to FIGS. 12 and 21 through 23, a second insulating layer INS2 including openings OP is formed on the top surfaces of the light-emitting elements LE (S140).

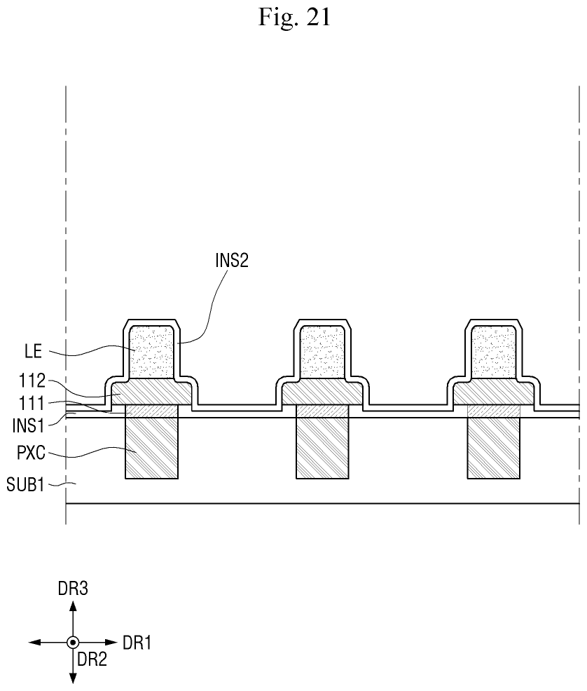

Specifically, referring to FIG. 21, the second insulating layer INS2 is deposited to cover the entire surface of the first substrate SUB1 where the light-emitting elements LE are disposed. The second insulating layer INS2 may be formed as an inorganic film such as a SiO₂ film, an Al₂O₃ film, and/or a HfOₓ film.

The second insulating layer INS2 may be formed on the top surface and the side surfaces of each of the light-emitting elements LE, the side surfaces of each of the connecting electrodes 112, and the first insulating layer INS1.

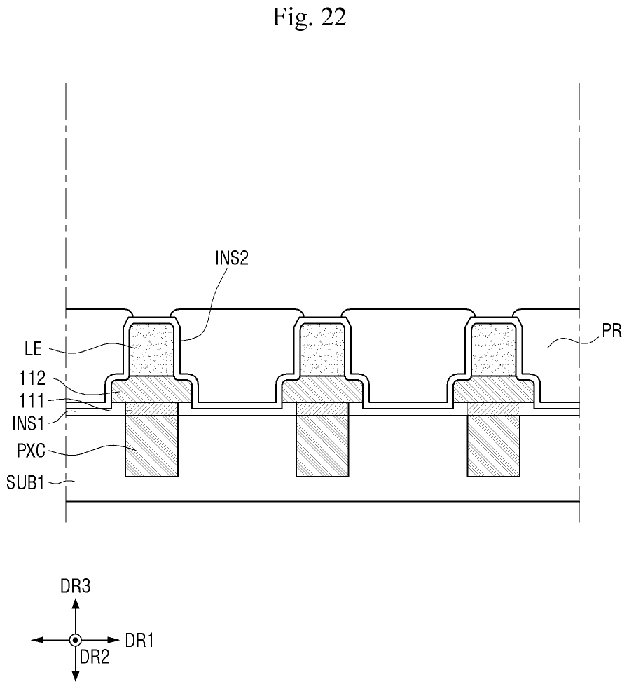

Referring to FIG. 22, photoresist patterns PR are formed on the second insulating layer INS2. The photoresist patterns PR may be disposed in all regions other than regions where openings OP are to be formed.

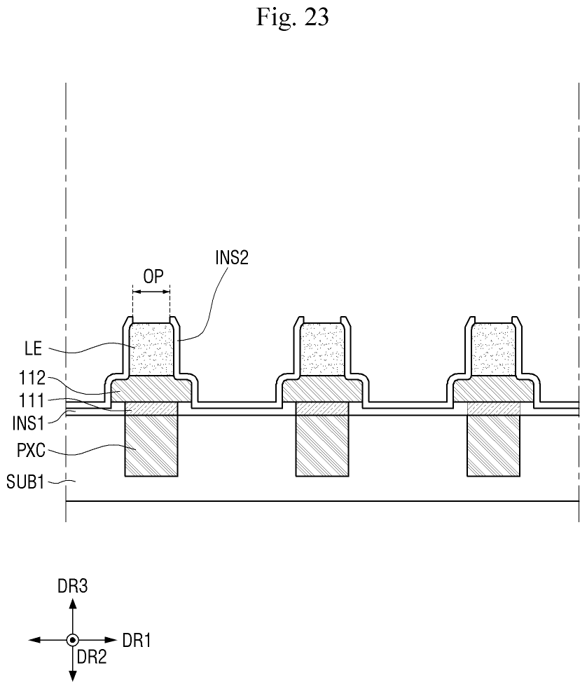

Thereafter, referring to FIG. 23, parts of the second insulating layer INS2 on the top surfaces of the light-emitting elements LE, not covered by the photoresist patterns PR, are removed. As a result, the openings OP are formed above the light-emitting elements LE, and thus, the top surfaces of the light-emitting elements LE are exposed. Thereafter, the photoresist patterns PR are removed by ashing.

Thereafter, referring to FIGS. 12, 24, and 25, a common electrode CE is deposited on the second insulating layer INS2 and the top surfaces of the light-emitting elements LE, not covered by the second insulating layer INS2, and a third insulating layer INS3 is formed (S150).

The common electrode CE may include a TCO such as ITO and/or IZO.

The third insulating layer INS3 may be formed as an inorganic film such as a SiO₂ film, an Al₂O₃ film, and/or a HfOₓ film.

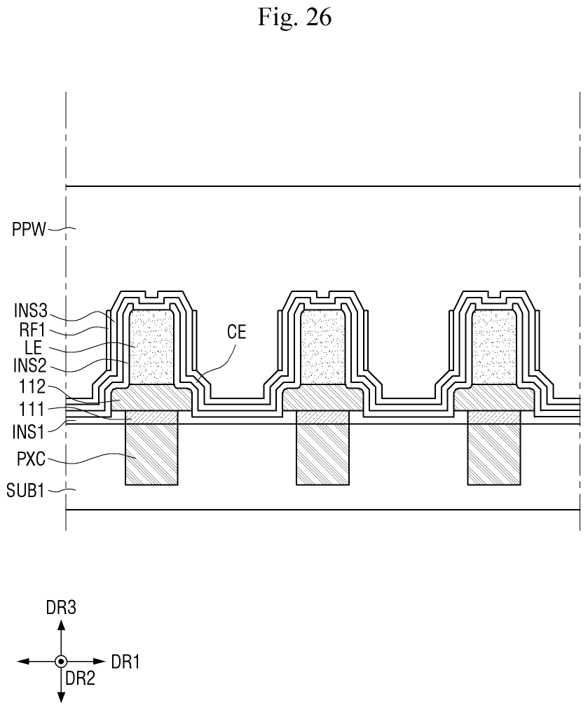

Thereafter, referring to FIGS. 26 through 29, a partition wall PW, a reflective film RF, and wavelength conversion layers QDL may be formed.

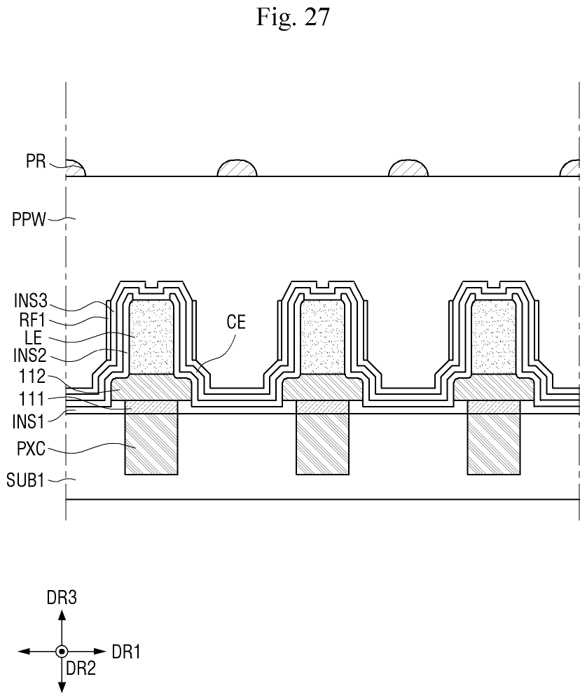

Specifically, referring to FIG. 26, an organic material PPW is applied on the third insulating layer INS3. Thereafter, referring to FIG. 27, photoresist patterns PR are formed in a non-emission area NEA as a mask. Thereafter, the partition wall PW is formed by patterning the organic material PPW. Openings may be formed in emission areas (EA1 through EA3) due to the presence of the photoresist patterns PR in the non-emission area NEA. Thereafter, the photoresist patterns PR are removed.

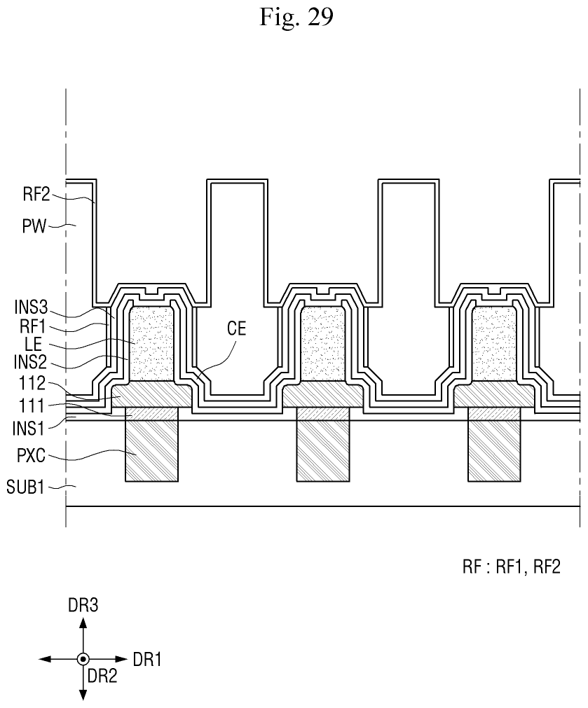

Referring to FIG. 29, a reflective film RF is deposited to cover the first substrate SUB1 where the partition wall PW is formed.

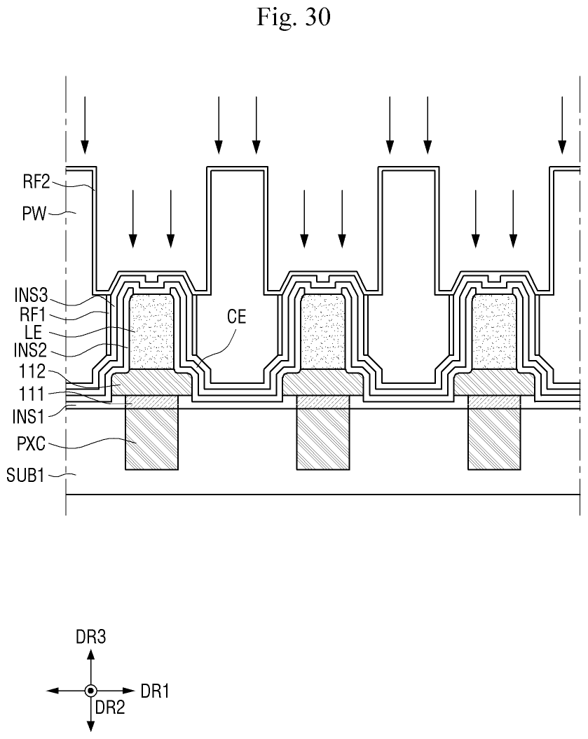

Thereafter, the reflective film RF (e.g., RF1, RF2) is etched by generating a large voltage difference in a third direction DR3 without using a particular mask and using an etching material. In this case, the etching material may etch the reflective layers RF while moving in the third direction DR3, i.e., in a top-to-bottom direction, through voltage control. As a result, referring to FIG. 30, reflective layers RF on a horizontal plane defined by first and second directions DR1 and DR2 may be removed, but reflective layers RF on a vertical plane defined by the third direction DR3 may not be removed. Thus, reflective layers RF on the top surface of the third insulating layer INS3 may be removed from the partition wall PW and first through third emission areas EA1 through EA3. Reflective layers RF on the side surfaces of the partition wall PW may not be removed. Accordingly, the reflective layers RF may be disposed on the side surfaces of the partition wall PW, in each of the first through third emission areas EA1 through EA3.

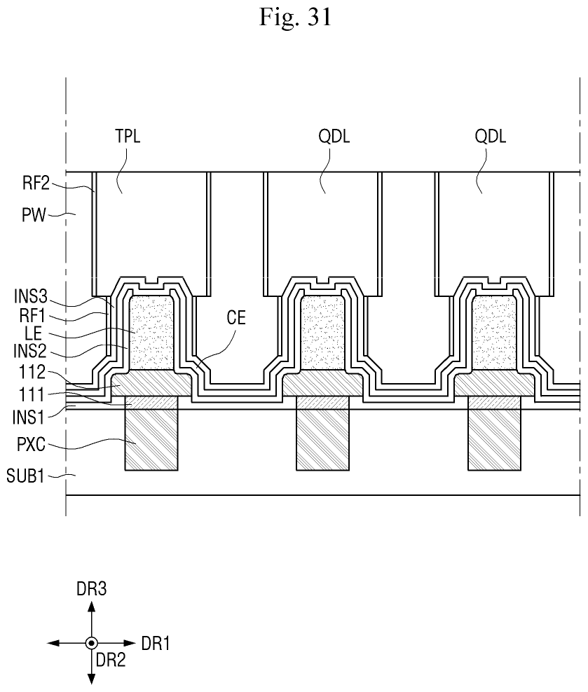

Referring to FIG. 31, a light-transmitting layer TPL and wavelength conversion layers QDL are formed in the openings in the partition wall PW. The light-transmitting layer TPL and the wavelength conversion layers QDL may be formed to fill the openings. The wavelength conversion layers QDL may be formed by a solution process (e.g., inkjet printing or imprinting) using a solution in which wavelength conversion particles are mixed with a base resin, but the present disclosure is not limited thereto. The light-transmitting layer TPL and the wavelength conversion layers QDL may be formed in the openings in the partition wall PW and may overlap with the emission areas (EA1 through EA3).

As fine light-emitting elements and fine connecting electrodes can be formed by using hard mask patterns having a stepped structure, the embodiment of FIG. 12 can be suitable for a high-resolution display device.

Also, as the boundaries between the connecting electrodes 112 and the first insulating layer INS1 are smooth, problems such as short circuits at corners during the formation of a common electrode can be reduced.

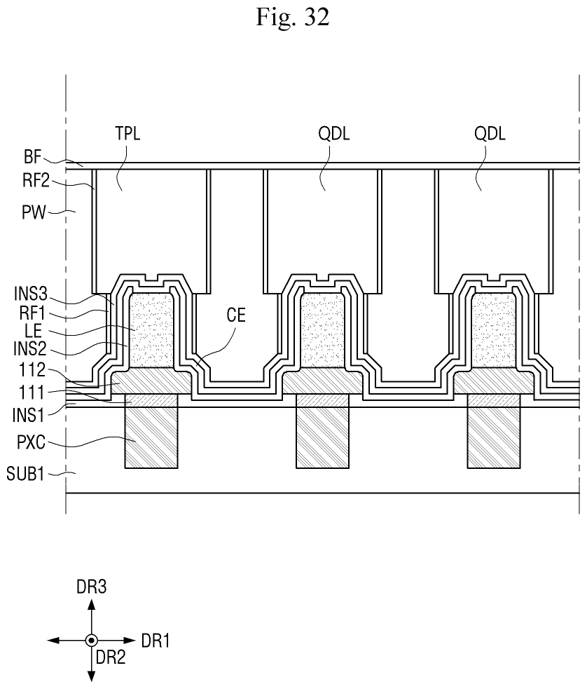

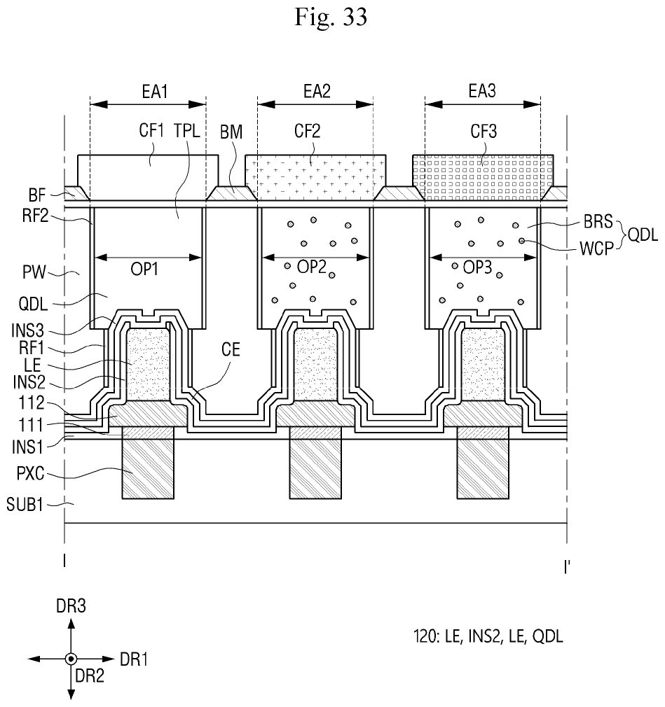

Thereafter, referring to FIGS. 32 and 33, a buffer layer BF and a plurality of color filters (CF1 through CF3) are formed.

Specifically, referring to FIG. 32, the buffer layer BF is formed to cover the top surface of the partition wall PW, the top surface of the light-transmitting layer TPL, the top surfaces of the wavelength conversion layers QDL, and the top surfaces of the reflective layers RF.

Thereafter, referring to FIG. 33, a light-blocking member BM is formed on the partition wall PW. The light-blocking member BM is formed by applying a light-blocking material and patterning the light-blocking material. The light-blocking member BM may be formed to overlap with the non-emission area NEA, but not with the emission areas (EA1 through EA3). Thereafter, a first color filter CF1 is formed on the light-transmitting layer TPL, which is defined by the light-blocking member BM. The first color filter CF1 may be formed by a photolithographic process. The first color filter CF1 may be formed to have a thickness of 1 μm or less, but the present disclosure is not limited thereto. Similarly, second and third color filters CF2 and CF3 are also formed by patterning to overlap with their respective openings in the partition wall PW.

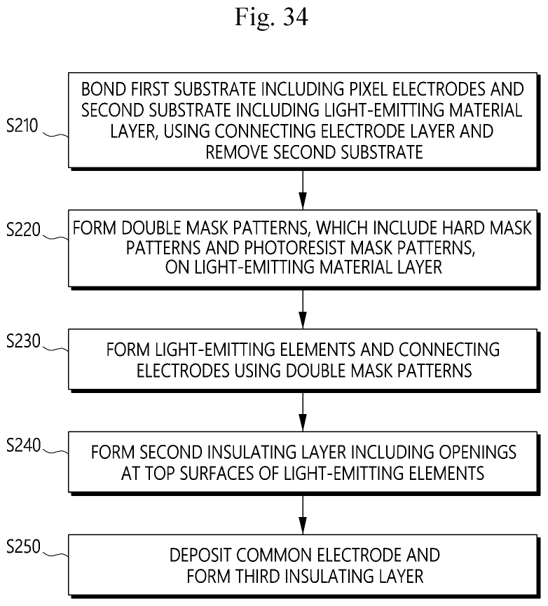

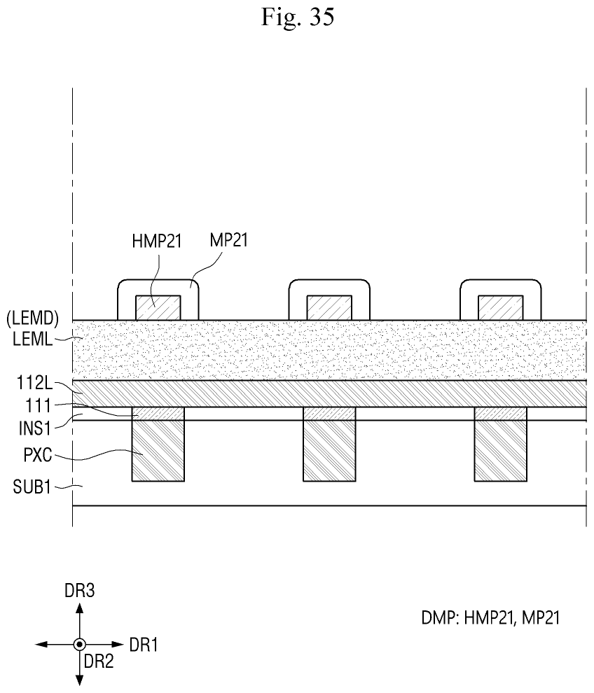

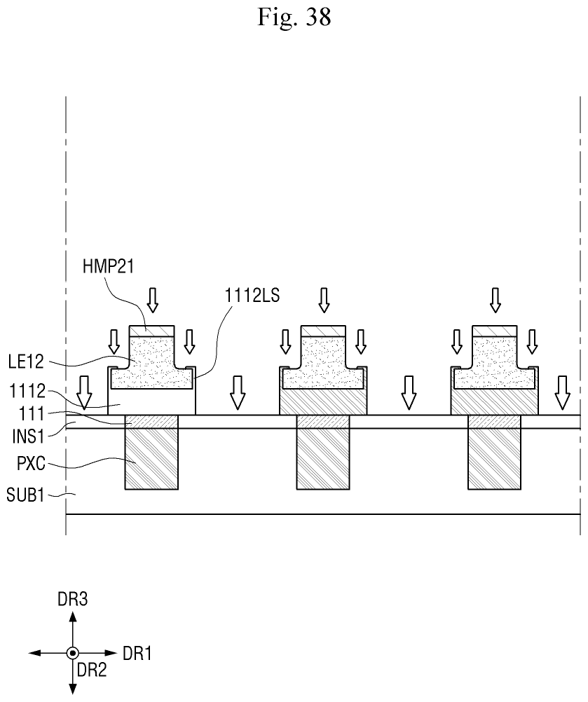

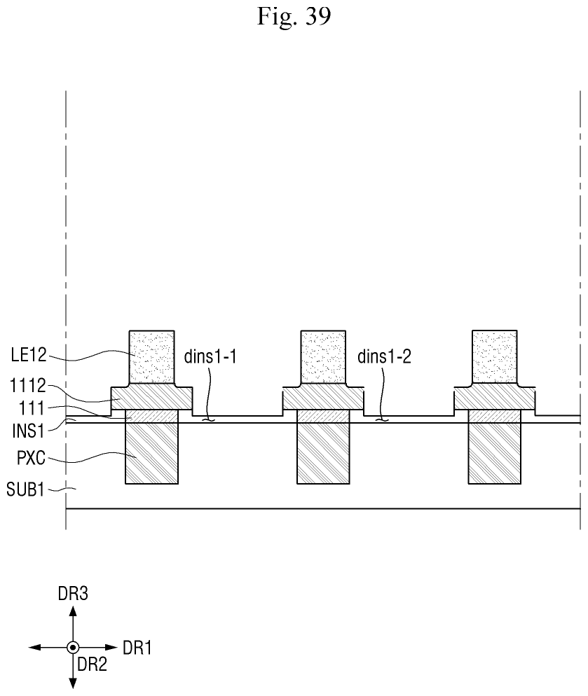

FIG. 34 is a flowchart illustrating a method of fabricating a display device according to one or more embodiments of the present disclosure. FIGS. 35 through 41 are cross-sectional views illustrating the method of FIG. 34.

Referring to FIG. 34, a first substrate SUB1 including pixel electrodes 111 and a second substrate SUB2 including a light-emitting material layer LEML are bonded with a connecting electrode layer 112L, and the second substrate SUB2 is removed (S210).

S210 of FIG. 34 is the same as S110 of FIG. 12, and thus, a detailed description thereof will be omitted.

Thereafter, referring to FIGS. 34 and 35, double mask patterns DMP, which include hard mask patterns HMP21 and photoresist mask patterns MP21, are formed on the light-emitting material layer LEML (S220).

Specifically, the hard masks HMP21 may be formed, and the photoresist mask patterns MP21 may be formed to surround the side surfaces and the top surface of each of the hard mask patterns HMP21. The hard mask patterns HMP21 may be disposed in regions where light-emitting elements LE are to be formed, and may be formed to have the same diameter as the light-emitting elements LE.

Referring to FIGS. 34 and 36 through 39, light-emitting elements LE12 and connecting electrodes 1112 are formed using the double mask patterns DMP (S230).

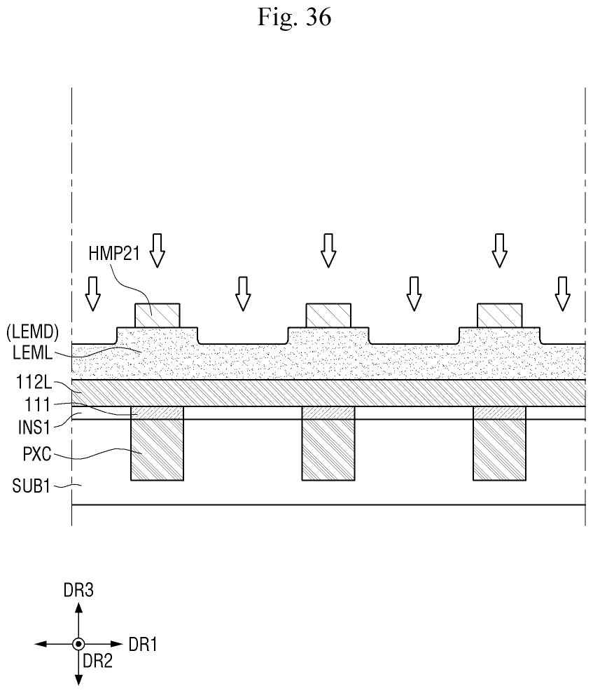

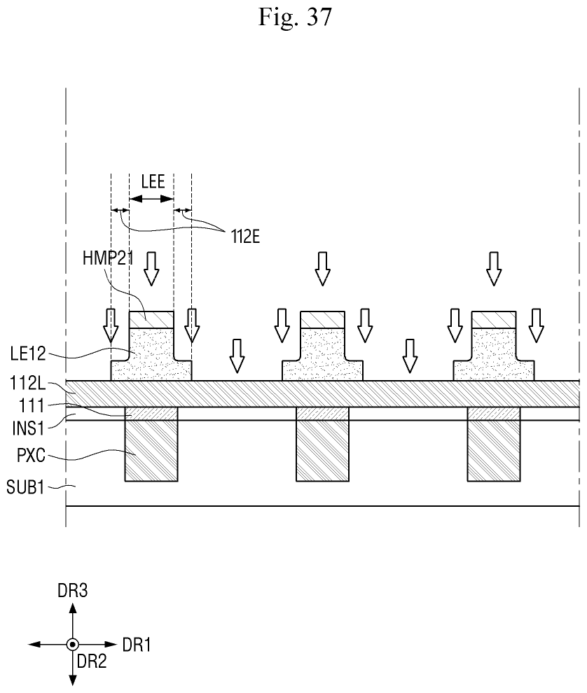

Specifically, referring to FIGS. 36 and 37, light-emitting element regions LEE by performing a primary etching process on the light-emitting material layer LEML using the photoresist mask patterns MP21, and connecting electrode regions 112E are defined by performing a secondary etching process on the connecting electrode layer 112L.

As the secondary etching process is continued, parts of the connecting electrode layer 112L where the double mask patterns DMP are not disposed are removed. As the etching of the connecting electrode layer 112L proceeds, nonvolatile particles of the connecting electrode layer 112L may stick to the side surfaces of each of the light-emitting elements LE12 and may thus form sidewalls 1112LS. The sidewalls 1112LS may cause defects during the driving of the light-emitting elements LE12.

Thereafter, a tertiary etching process is performed, and as a result, the light-emitting elements LE21 and the connecting electrodes 1112 are formed. During the tertiary etching process, the sidewalls 1112LS, which are formed on the side surfaces of each of the light-emitting elements LE12, may be removed.

The same etching gas may be used to form the light-emitting elements LE12 and the connecting electrodes 1112. Thus, etching processes for forming the light-emitting elements LE12 and the connecting electrodes 1112 may be performed one after another in the same chamber.

Light-emitting element regions LEE correspond to regions where the hard mask patterns HMP21 are disposed, and connecting electrode regions 112E correspond to regions where the photoresist mask patterns MP21 are disposed.

As upper parts of a first insulating layer INS1 on the first substrate SUB1 where pixel electrodes 111 are not disposed are etched by the tertiary etching process, the first insulating layer INS1 may be formed to have a stepped structure. The first insulating layer INS1 may be formed to have a first thickness dins1-1 in areas overlapping with the connecting electrodes 1112 and a second thickness dins1-2 in areas not overlapping with the connecting electrodes 1112. The first thickness dins1-1 may be greater than the second thickness dins1-2. That is, the first insulating layer INS1 may be formed to be thicker in the areas overlapping with the connecting electrodes 1112 than in the areas not overlapping with the connecting electrodes 1112.

The first insulating layer INS1 may be formed as an inorganic film such as a SiO₂ film, an Al₂O₃ film, and/or a HfOₓ film.

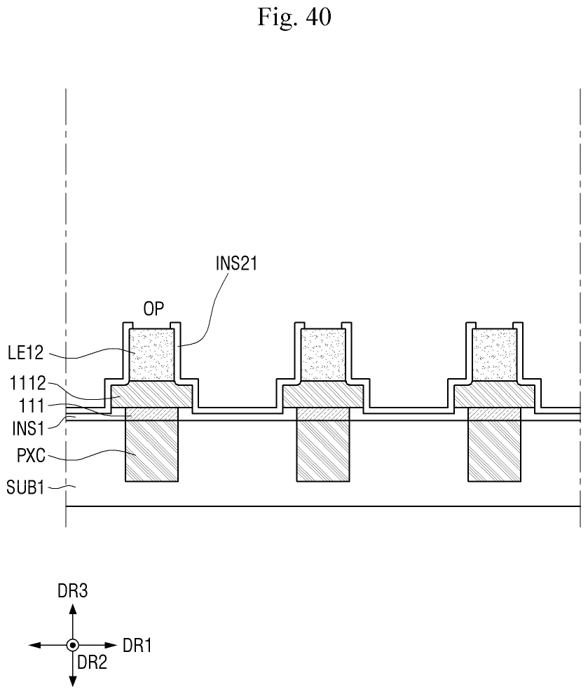

Referring to FIGS. 34 and 40, a second insulating layer INS21 including openings OP is formed on the top surfaces of the light-emitting elements LE12 (S240).

The second insulating layer INS21 may be formed as an inorganic film such as a SiO₂ film, an Al₂O₃ film, and/or a HfOₓ film.

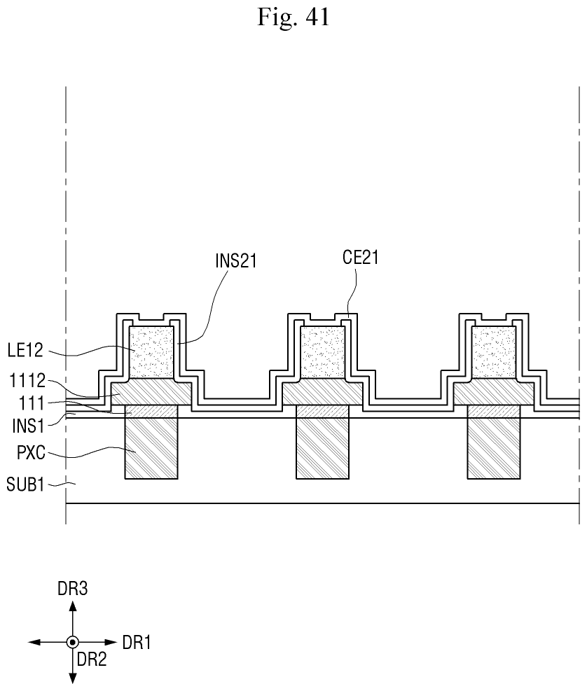

Referring to FIGS. 34 and 41, a common electrode CE21 is deposited on the top surfaces of the light-emitting elements LE12, not covered by the second insulating layer INS21, and a third insulating layer INS3 is formed (S250).

The common electrode CE21 may include a TCO such as ITO and/or IZO. S240 and S250 of FIG. 34 are similar to S140 and S150, respectively, of FIG. 12, and thus, detailed descriptions thereof will be omitted.

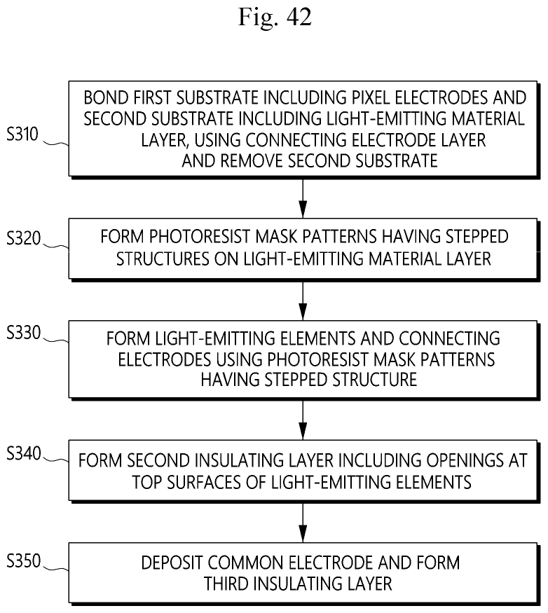

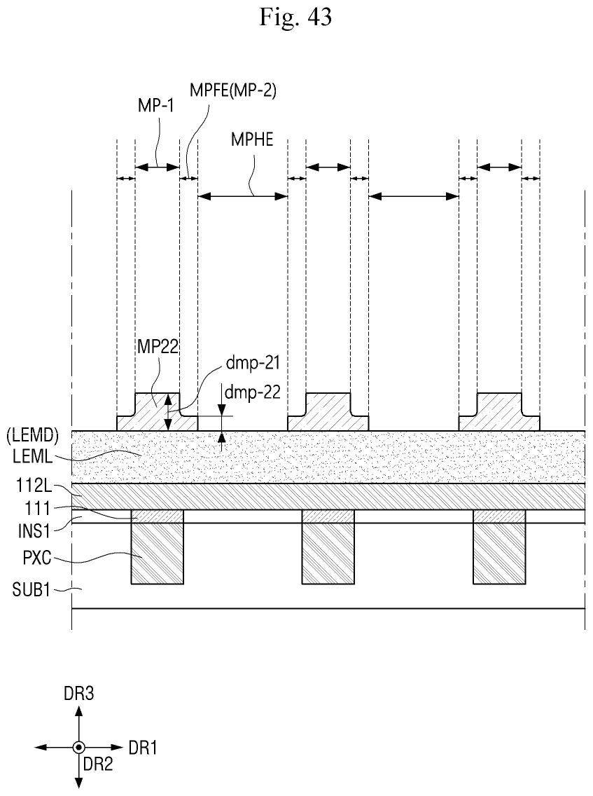

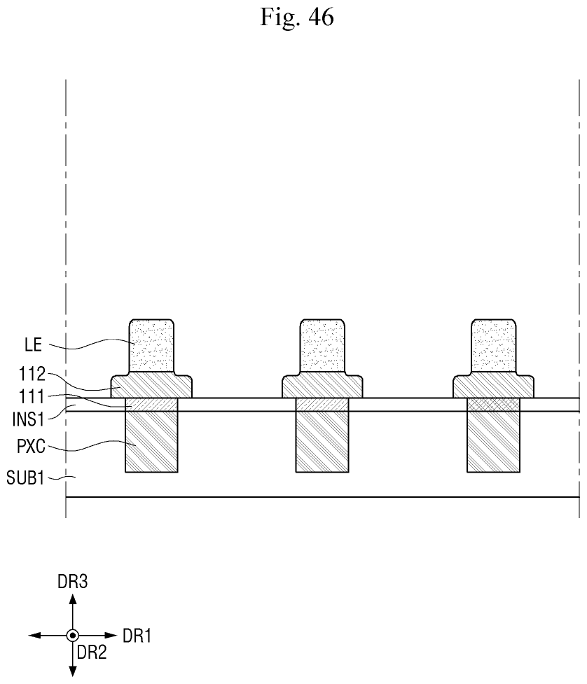

FIG. 42 is a flowchart illustrating a method of fabricating a display device according to one or more embodiments of the present disclosure. FIGS. 43 through 48 are cross-sectional views illustrating the method of FIG. 42.

Referring to FIG. 42, a first substrate SUB1 including pixel electrodes 111 and a second substrate SUB2 including a light-emitting material layer LEML are bonded with a connecting electrode layer 112L, and the second substrate SUB2 is removed (S310).

S310 of FIG. 42 is the same as S110 of FIG. 12, and thus, a detailed description thereof will be omitted.

Referring to FIGS. 42 and 43, photoresist mask patterns MP22 having a stepped structure are formed on a light-emitting material layer LEML (S320).

Specifically, the photoresist mask pattern MP22 may be formed to have a stepped structure. The photoresist mask patterns MP22 may include middle parts MP-1 and edge parts MP-2, which surround the middle parts MP-1.

The middle parts MP-1 of the photoresist mask patterns MP22 may be disposed in regions where light-emitting elements LE are to be formed. The edge parts MP-2 of the photoresist mask patterns MP22 may be disposed in regions where connecting electrodes 112 are to be formed.

A thickness dmp-21 of the middle parts MP-1 in the third direction DR3 may be greater than a thickness dmp-22 of the edge parts MP-2 in the third direction DR3. The photoresist mask patterns MP22 may be formed by transferring photoresist using a halftone mask. Photoresist is a photosensitive material obtained by organically dissolving resin with a photosensitizer. The photoresist mask patterns MP22 may be formed by full exposure and half exposure. For example, parts of photoresist that are subject to full exposure may receive all irradiated light and may thus react with all thicknesses, and parts of photoresist that are subject to half exposure may receive only some of the irradiated light and may thus react with only particular thicknesses. By performing full exposure and half exposure on photoresist and developing exposed parts of the photoresist, full exposure regions MPFE and half exposure regions MPHE are formed. Due to the half exposure regions MPHE, the photoresist mask patterns MP22 having a stepped structure are formed.

Referring to FIGS. 42 and 44 through 46, light-emitting elements LE and connecting electrodes 112 are formed using double mask patterns DMP (S330).

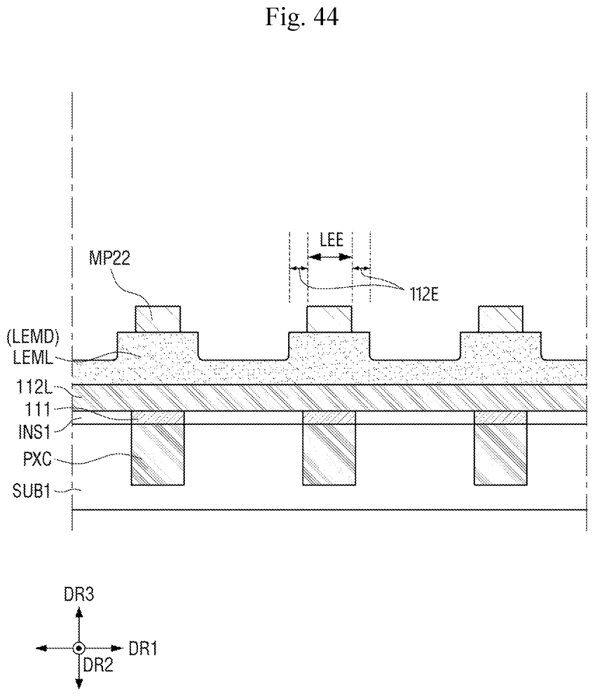

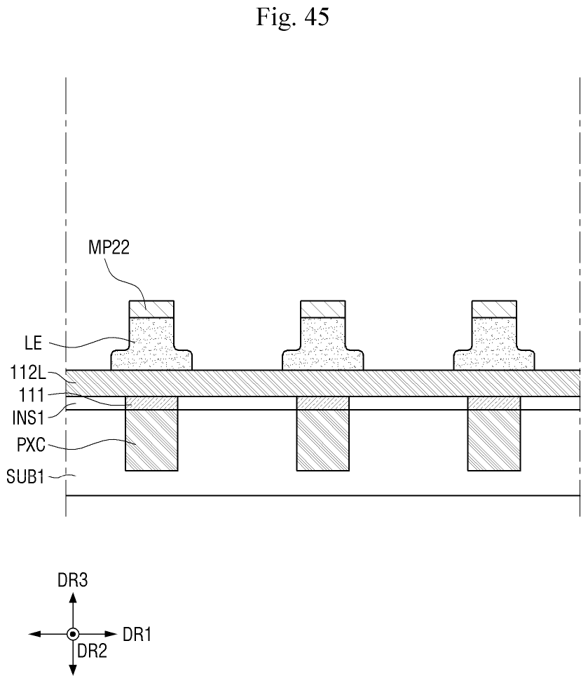

Specifically, referring to FIGS. 44 and 45, a primary etching process is performed on the light-emitting material layer LEML until the edge parts MP-2 of the photoresist mask patterns MP22 are removed. As a result of the primary etching process, light-emitting element regions LEE may be defined. A secondary etching process is performed on the connecting electrode layer 112L, thereby defining connecting electrode regions 112E. During the secondary etching process, a nonvolatile material from the connecting electrode layer 112L may stick to the side surfaces of each of the light-emitting elements LE and may thus form sidewalls 112LS, which are connected to the connecting electrodes 112. If the sidewalls 112LS are not removed, defects may be caused to the light-emitting elements LE.

Thereafter, a tertiary etching process is performed, and as a result, the light-emitting elements LE and the connecting electrodes 112 are formed. During the tertiary etching process, the sidewalls 112LS, which are formed on the side surfaces of each of the light-emitting elements LE, may be removed.

The same etching gas may be used to form the light-emitting elements LE and the connecting electrodes 112. Thus, etching processes for forming the light-emitting elements LE and the connecting electrodes 112 may be performed one after another in the same chamber.

As upper parts of a first insulating layer INS1 on the first substrate SUB1 where pixel electrodes 111 are not disposed are etched by the tertiary etching process, the first insulating layer INS1 may be formed to have a stepped structure. The first insulating layer INS1 may be formed to be thicker in areas overlapping with the connecting electrodes 112 than in areas not overlapping with the connecting electrodes 112.

The first insulating layer INS1 may be formed as an inorganic film such as a SiO₂ film, an Al₂O₃ film, and/or a HfOₓ film.

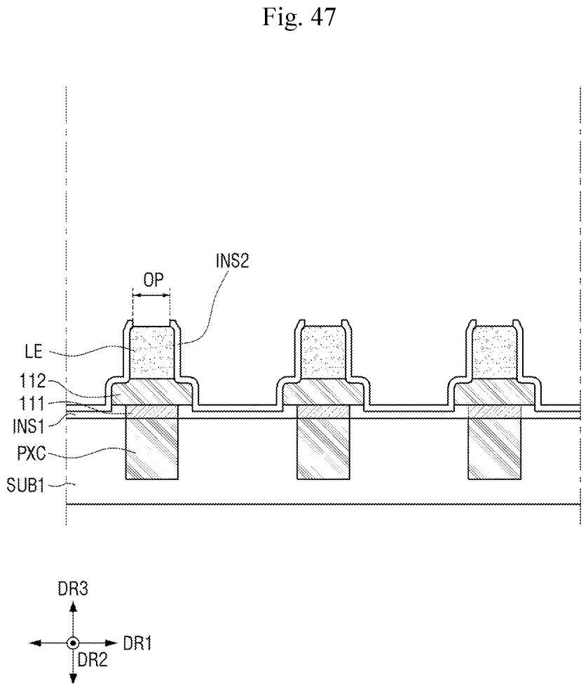

Referring to FIGS. 42 and 47, a second insulating layer INS2 including openings OP is formed on the top surfaces of the light-emitting elements LE (S340).

The second insulating layer INS2 may be formed as an inorganic film such as a SiO₂ film, an Al₂O₃ film, or a HfOₓ film.

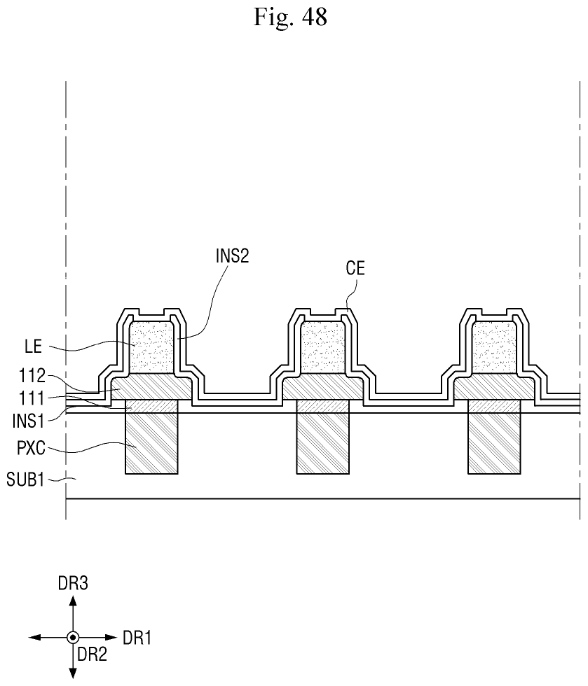

Referring to FIGS. 42 and 48, a common electrode CE is deposited on the top surfaces of the light-emitting elements LE, not covered by the second insulating layer INS2, and a third insulating layer INS3 is formed (S350).

The common electrode CE may include a TCO such as ITO and/or IZO.

S340 and S350 of FIG. 42 are similar to S140 and S150, respectively, of FIG. 12, and thus, detailed descriptions thereof will be omitted.

According to the embodiment of FIGS. 42 through 48, any defects that may be caused by unwanted sidewalls formed on the sides of each light-emitting element due to the rearrangement of an element for forming connecting electrodes can be addressed.

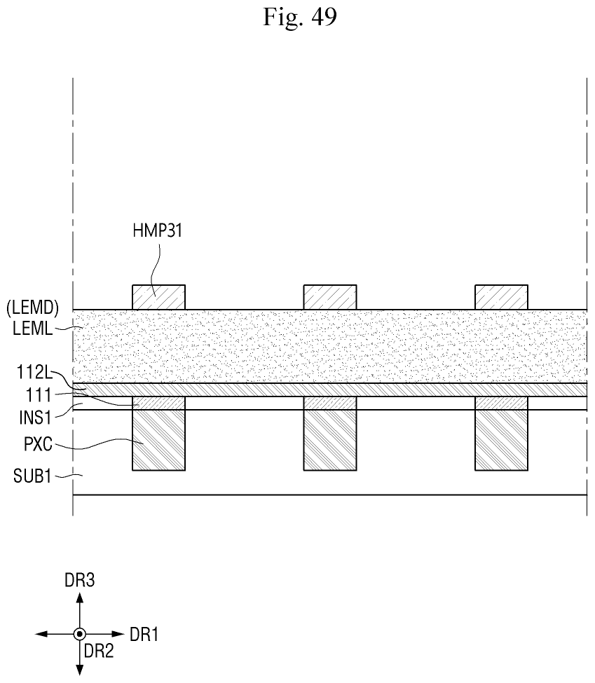

FIGS. 49 through 55 are cross-sectional views illustrating a method of fabricating a display panel using a double mask according to one or more embodiments of the present disclosure.

The embodiment of FIGS. 49 through 55 forms connecting electrodes using a double mask.

As already described above with reference to FIGS. 13 and 14, a first substrate SUB1 including pixel electrodes 111 and a second substrate SUB2 including a light-emitting material layer LEML are bonded with a connecting electrode layer 112L, and the second substrate SUB2 is removed.

Thereafter, referring to FIG. 49, hard mask patterns HMP31 are formed on the light-emitting material layer LEML.

The hard mask patterns HMP31 may be disposed in regions where light-emitting elements LE are to be formed and may be formed to have the same diameter as the light-emitting elements LE.

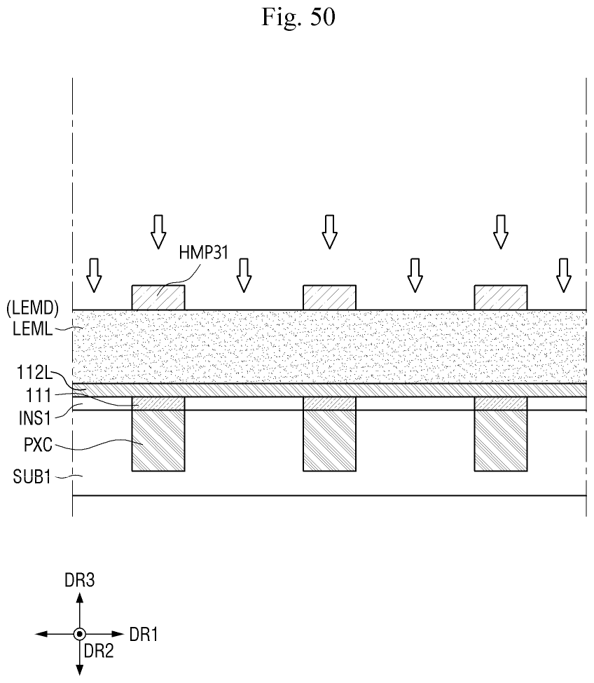

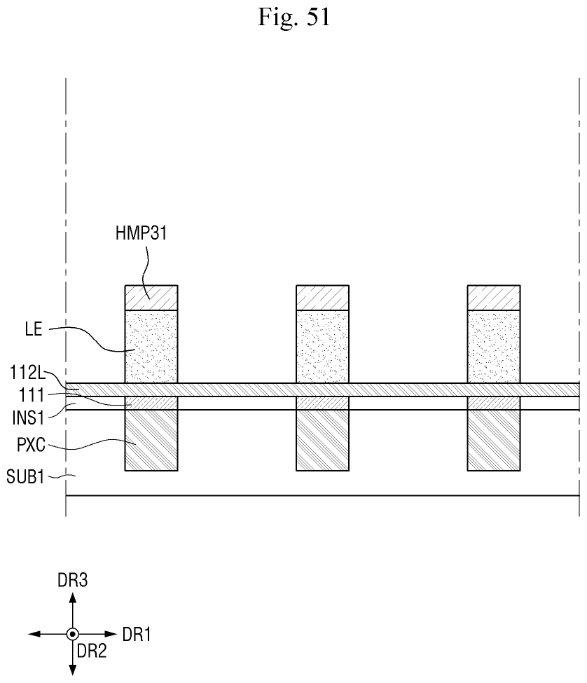

Thereafter, referring to FIGS. 50 and 51, the light-emitting elements LE are formed by performing a primary etching process on the light-emitting material layer LEML using the hard mask patterns HMP31.

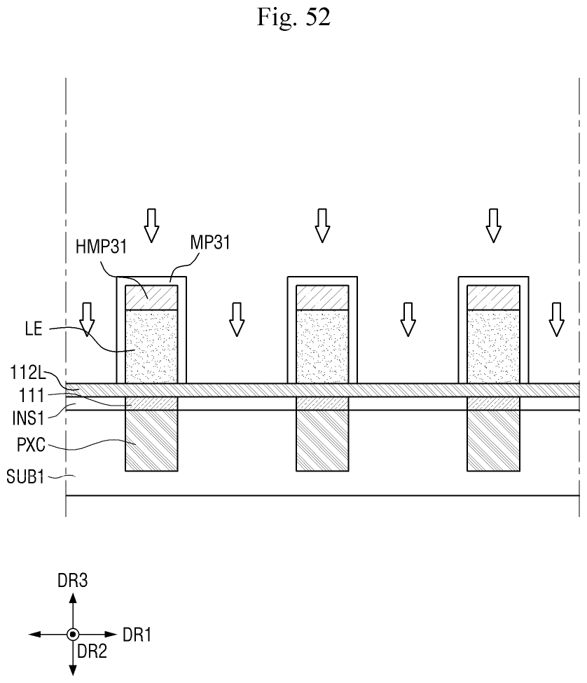

Thereafter, referring to FIG. 52, photoresist mask patterns MP31 are formed to surround the top surface and the side surfaces of each of the hard mask patterns HMP31.

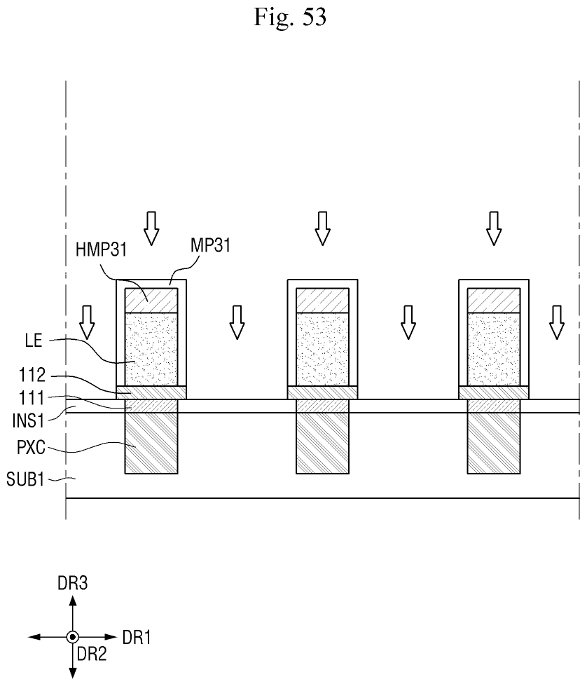

Thereafter, referring to FIG. 53, connecting electrodes 112 are formed by etching the connecting electrode layer 112L using the photoresist mask patterns MP31.

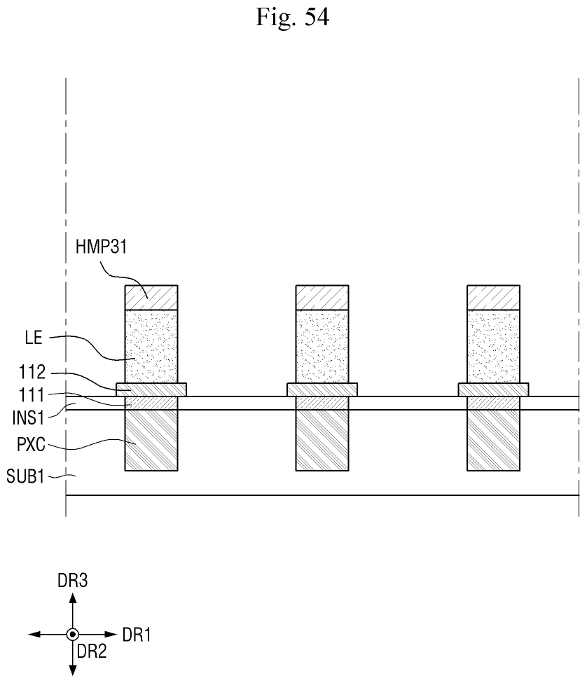

Thereafter, referring to FIG. 54, the photoresist mask patterns MP31 are removed.

Thereafter, the hard mask patterns HMP31 are removed from above the light-emitting elements LE.

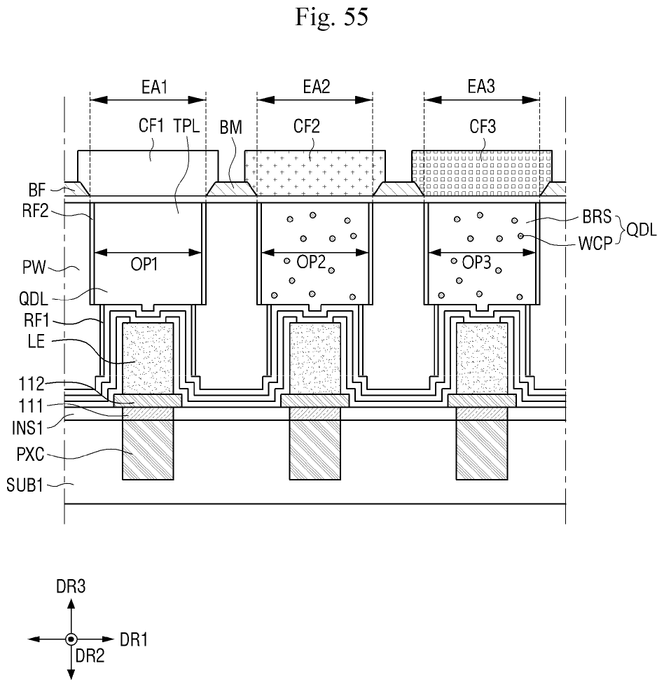

Thereafter, referring to FIG. 55, a second insulating layer INS2, a common electrode CE, a third insulating layer INS3, first reflective layers RF1, second reflective layers RF2, a partition wall PW, a light-transmitting layer TPL, the wavelength conversion layers QDL, and a color filter layer CFL may be further formed on the light-emitting elements LE, as already described above with reference to FIGS. 21 through 32. Detailed descriptions of how to form the second insulating layer INS2, the common electrode CE, the third insulating layer INS3, the first reflective layers RF1, the second reflective layers RF2, the partition wall PW, a light-transmitting layer TPL, the wavelength conversion layers QDL, and the color filter layer CFL will be omitted.

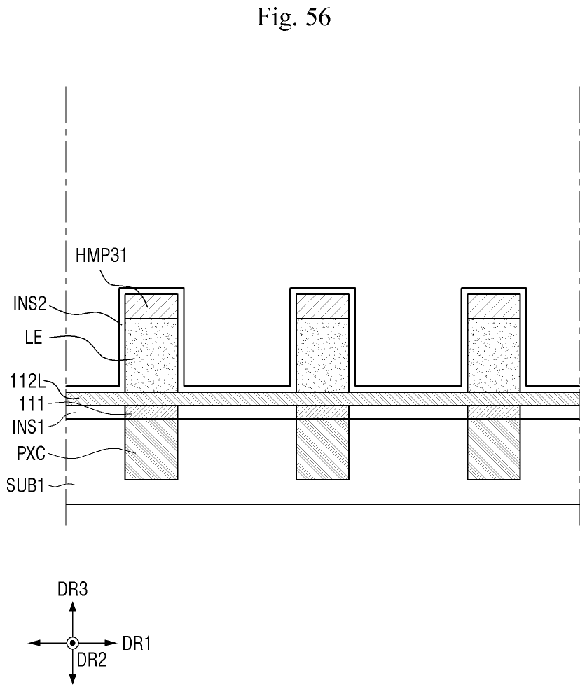

FIGS. 56 through 60 are cross-sectional views illustrating a method of fabricating a display panel using a double mask according to one or more embodiments of the present disclosure.

The embodiment of FIGS. 56 through 60 forms connecting electrodes using a single mask.

Referring to FIG. 56, hard mask patterns HMP31 are formed on a light-emitting material layer LEML, as already described above with reference to FIG. 49, and a second insulating layer INS2 is formed on the hard mask patterns HMP31 and light-emitting elements LE. The second insulating layer INS2 is formed on the top surface and the side surfaces of each of the hard mask patterns HMP31, the side surfaces of each of the light-emitting elements LE, and a connecting electrode layer 112L.

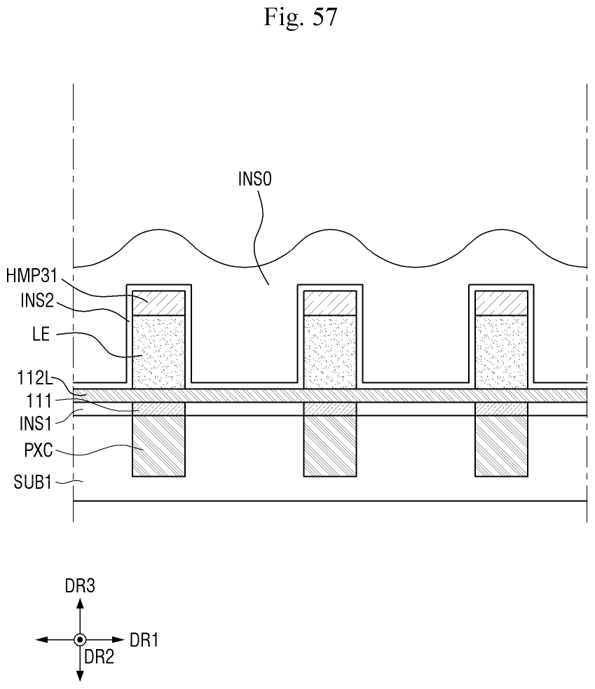

Thereafter, referring to FIG. 57, a passivation layer INS0 is formed on the second insulating layer INS2 to cover and planarize the light-emitting elements LE.

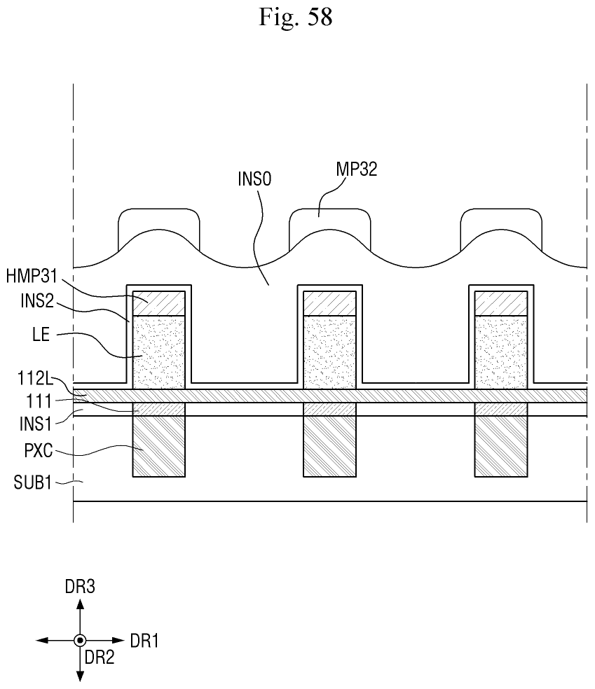

Thereafter, referring to FIG. 58, photoresist mask patterns MP32 are formed on the second insulating layer INS2, in areas overlapping with the light-emitting elements LE. The photoresist mask patterns MP32 are formed to completely cover the light-emitting elements LE.

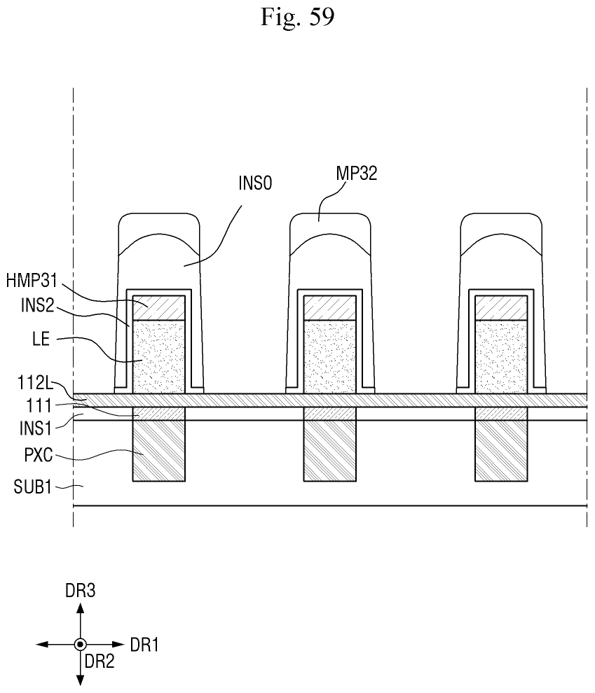

Thereafter, referring to FIG. 59, the passivation layer INS0 is etched using the photoresist mask patterns MP32. The second insulating layer INS2 may also be etched in areas not overlapping with the photoresist mask patterns MP32. As a result, the connecting electrode layer 112L is exposed in the areas not overlapping with the photoresist mask patterns MP32.

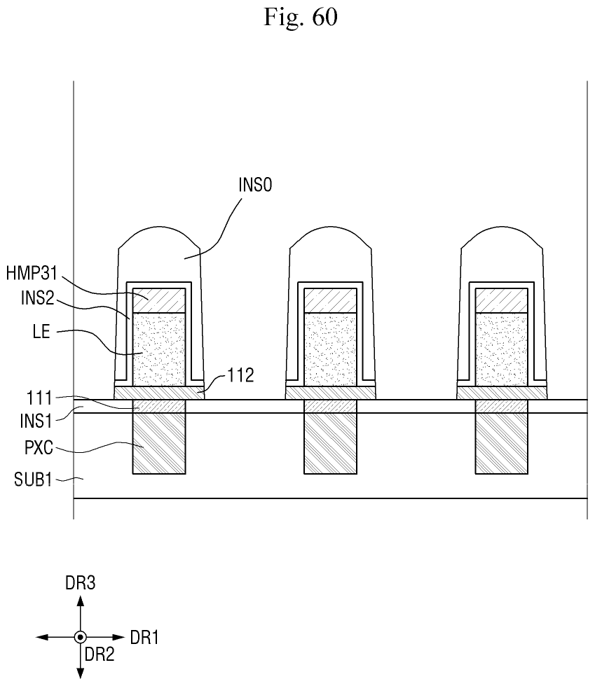

Thereafter, referring to FIG. 60, connecting electrodes 112 are formed by etching the connecting electrode layer 112L using the photoresist mask patterns MP32. In this process, the photoresist mask patterns MP32 may be etched away.

Thereafter, the passivation layer INS0 and the hard mask patterns HMP31 are removed. Thereafter, as already described above with reference to FIGS. 21 through 32, a second insulating layer INS2, a common electrode CE, a third insulating layer INS3, first reflective layers RF1, second reflective layers RF2, a partition wall PW, a light-transmitting layer TPL, wavelength conversion layers QDL, and a color filter layer CFL may be further formed on the light-emitting elements LE. Detailed descriptions of how to form the second insulating layer INS2, the common electrode CE, the third insulating layer INS3, the first reflective layers RF1, the second reflective layers RF2, the partition wall PW, the light-transmitting layer TPL, the wavelength conversion layers QDL, and the color filter layer CFL will be omitted.

The display panel obtained by the method of FIGS. 56 through 60 may be as illustrated in FIG. 55.

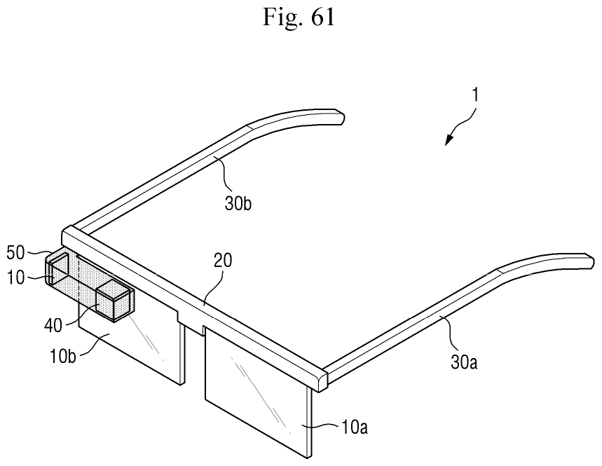

FIG. 61 is an example diagram illustrating a virtual reality device including a display device according to one or more embodiments. FIG. 61 illustrates a virtual reality device 1 in which the display device 10 according to one or more embodiments is used.

Referring to FIG. 61, the virtual reality device 1 according to one or more embodiments may be a device in a form of glasses. The virtual reality device 1 according to one or more embodiments may include a display device 10, a left-eye lens 10a, a right-eye lens 10b, a support frame 20, left and right legs 30a and 30b, a reflective member 40, and a display device housing 50.

FIG. 61 illustrates the virtual reality device 1 including the two legs 30a and 30b. However, the present disclosure is not limited thereto. The virtual reality device 1 according to one or more embodiments may be used in a head-mounted display including a head-mounted band that may be mounted on a head instead of the legs 30a and 30b. For example, the virtual reality device 1 according to one or more embodiments may not be limited to the example shown in FIG. 61, and may be applied in various forms and in various electronic devices.

The display device housing 50 may receive the display device 10 and the reflective member 40. An image displayed on the display device 10 may be reflected from the reflective member 40 and provided to a user's right eye through the right-eye lens 10b. Thus, the user may view a virtual reality image displayed on the display device 10 via the right eye.

FIG. 61 illustrates that the display device housing 50 is disposed at a right end of the support frame 20. However, the present disclosure is not limited thereto. For example, the display device housing 50 may be disposed at a left end of the support frame 20. In this case, the image displayed on the display device 10 may be reflected from the reflective member 40 and provided to the user's left eye via the left-eye lens 10a. Thus, the user may view the virtual reality image displayed on the display device via the left eye. As another example, the display device housing 50 may be disposed at each of the left end and the right end of the support frame 20. In this case, the user may view the virtual reality image displayed on the display device 10 via both the left eye and the right eye.

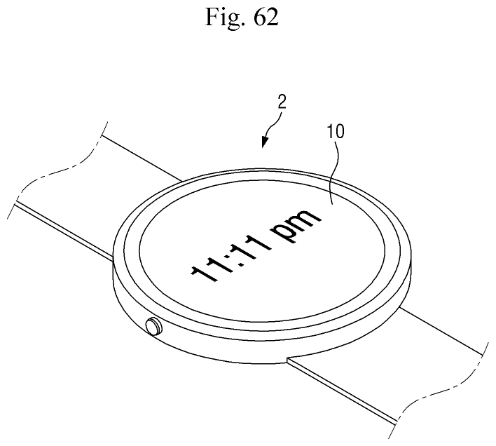

FIG. 62 is an example diagram illustrating a smart device including a display device according to one or more embodiments.

Referring to FIG. 62, a display device 10 according to one or more embodiments may be applied to a smart watch 2 as one of smart devices.

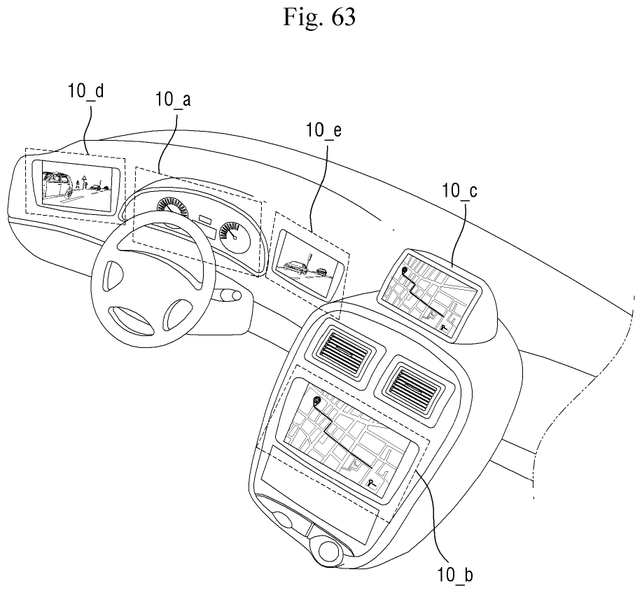

FIG. 62 is an example diagram illustrating a vehicle including a display device according to one or more embodiments. FIG. 63 illustrates a vehicle in which display devices according to one or more embodiments are used.

Referring to FIG. 63, the display devices 10_a, 10_b, and 10_c according to one or more embodiments may be applied to the dashboard of the vehicle, applied to the center fascia of the vehicle, or applied to a CID (Center Information Display) disposed on the dashboard of the vehicle. Further, each of the display devices 10_d and 10_e according to one or more embodiments may be applied to each room mirror display that replaces each of side-view mirrors of the vehicle.

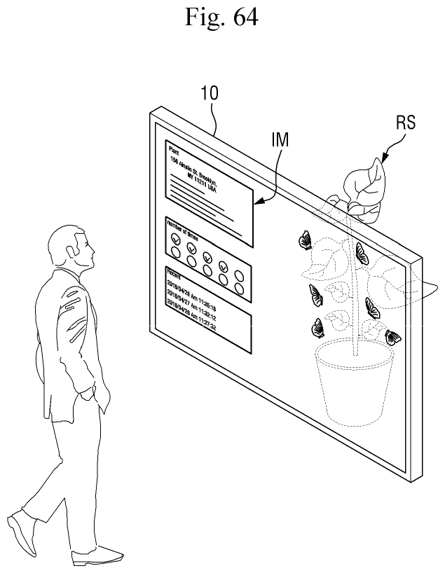

FIG. 64 is an example diagram illustrating a transparent display device including a display device according to one or more embodiments.

Referring to FIG. 64, a display device according to one or more embodiments may be applied to a transparent display device. The transparent display device may transmit light therethrough while displaying an image IM thereon. Therefore, a user located in front of the transparent display device may not only view the image IM displayed on the display device 10, but also view an object RS or a background located in rear of the transparent display device. In case that the display device 10 is applied to the transparent display device, the first substrate SUB1 of the display device 10 shown in FIG. 6 may include a light transmitting portion that may transmit light therethrough or may be made of a material that may transmit light therethrough.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A display device comprising:
a plurality of pixel electrodes on a substrate;
light-emitting elements on the plurality of pixel electrodes and extending in a thickness direction of the substrate; and
connecting electrodes between the plurality of pixel electrodes and the light-emitting elements, wherein:
a width of the connecting electrodes is greater than a width of the light-emitting elements; and
upper corners of each of the light-emitting elements and upper corners of each of the connecting electrodes are rounded.

2. The display device of claim 1, wherein corners at boundaries between the connecting electrodes and the light-emitting elements are rounded.

3. The display device of claim 1, wherein the connecting electrodes comprise a nonvolatile material comprising one or more selected from among gold (Au), copper (Cu), silver (Ag), and roentgenium (Rg).

4. The display device of claim 2, further comprising:
a first insulating layer between the pixel electrodes,
wherein the first insulating layer has a stepped structure.

5. The display device of claim 3, wherein:
the first insulating layer includes first areas overlapping with the connecting electrodes and second areas not overlapping with the connecting electrodes; and
a thickness of the first areas is greater than a thickness of the second areas.

6. The display device of claim 4, further comprising:
a second insulating layer covering a top surface and side surfaces of each of the light-emitting elements, parts of top surfaces of the connecting electrodes not overlapping the light-emitting elements, and side surfaces of each of the connecting electrodes,
wherein the second insulating layer includes openings at the top surfaces of the light-emitting elements and further comprises upper corners corresponding to the upper corners of each of the light-emitting elements and inclined parts at corners corresponding to the upper corners of each of the connecting electrodes.

7. The display device of claim 6, further comprising:
a common electrode on the second insulating layer,
wherein the common electrode is in contact with the light-emitting elements through the openings and comprises upper corners corresponding to the upper corners of each of the light-emitting elements and inclined parts at corners corresponding to the upper corners of each of the connecting electrodes.

8. The display device of claim 1, wherein each of the light-emitting elements comprises a first semiconductor layer, an electron blocking layer, an active layer, a superlattice layer, and a second semiconductor layer that are sequentially stacked in a third direction.

9. A method of fabricating a display device, comprising:
bonding a first substrate in which a plurality of pixel electrodes is located, and a second substrate on which a light-emitting material layer is located, with a connecting electrode layer and removing the second substrate;
forming hard mask patterns having a stepped structure on the light-emitting material layer;
forming light-emitting elements and connecting electrodes by etching the light-emitting material layer along the hard mask patterns; and
depositing a common electrode on the light-emitting elements, wherein:
the hard mask patterns comprise middle parts and edge parts located along peripheries of the middle parts; and
a thickness of the middle parts is greater than a thickness of the edge parts.

10. The method of claim 9, further comprising, before the depositing the common electrode:
forming a second insulating layer to cover a top surface and side surfaces of each of the light-emitting elements and a top surface and side surfaces of each of the connecting electrodes, wherein:
the second insulating layer includes openings at the top surfaces of the light-emitting elements; and
the common electrode is in contact with the top surfaces of the light-emitting elements through the openings.

11. The method of claim 9, wherein the connecting electrodes comprises a nonvolatile material comprising one or more selected from among gold (Au), copper (Cu), silver (Ag), and roentgenium (Rg).

12. The method of claim 10, wherein the forming the light-emitting elements and the connecting electrodes, comprises defining light-emitting element regions by performing a primary etching process on the light-emitting material layer until the edge parts are removed, defining connecting electrode regions by performing a secondary etching process on the connecting electrode layer, and forming the light-emitting elements and the connecting electrodes by performing a tertiary etching process on the light-emitting material layer and the connecting electrode regions.

13. The method of claim 12, wherein:
a width of the connecting electrodes is greater than a width of the light-emitting elements; and
upper corners of each of the light-emitting elements and upper corners of each of the connecting electrodes are rounded.

14. The method of claim 12, wherein:
the first substrate further comprises a first insulating layer between the pixel electrodes, and
the first insulating layer is formed to have a stepped structure by the tertiary etching process.

15. The method of claim 14, wherein:
the first insulating layer includes first areas overlapping with the connecting electrodes and second areas not overlapping with the connecting electrodes; and
a thickness of the first areas is greater than a thickness of the second areas.

16. The method of claim 13, further comprising, before the depositing the common electrode on the light-emitting elements:
forming a second insulating layer to cover a top surface and side surfaces of each of the light-emitting elements, parts of top surfaces of the connecting electrodes not overlapping the light-emitting elements, and side surfaces of each of the connecting electrodes, and to have openings at the top surfaces of the light-emitting elements,
wherein the second insulating layer comprises upper corners corresponding to the upper corners of each of the light-emitting elements and inclined parts at corners corresponding to the upper corners of each of the connecting electrodes.

17. The method of claim 16, wherein the depositing the common electrode on the light-emitting elements, comprises depositing the common electrode on the second insulating layer to be in contact with the light-emitting elements through the openings and to have upper corners corresponding to the upper corners of each of the light-emitting elements and inclined parts at corners corresponding to the upper corners of each of the connecting electrodes.

18. A method of fabricating a display device, comprising:
bonding a first substrate in which a plurality of pixel electrodes is located, and a second substrate on which a light-emitting material layer is located, with a connecting electrode layer and removing the second substrate;
forming double mask patterns comprising hard mask patterns and photoresist mask patterns, on the light-emitting material layer;
forming light-emitting elements and connecting electrodes by etching the light-emitting material layer along the double mask patterns; and
depositing a common electrode on the light-emitting elements, wherein:
the hard mask patterns define light-emitting element regions; and
the photoresist mask patterns are formed to surround a top surface and side surfaces of each of the hard mask patterns and define connecting electrode regions.

19. The method of claim 18, further comprising, before the depositing the common electrode:
forming a second insulating layer covering a top surface and side surfaces of each of the light-emitting elements and a top surface and side surfaces of each of the connecting electrodes, wherein:
the second insulating layer includes openings at the top surfaces of the light-emitting elements; and
the common electrode contacting with the top surfaces of the light-emitting elements through the openings.

20. The method of claim 18, wherein the connecting electrodes comprise a nonvolatile material comprising one or more selected from among gold (Au), copper (Cu), silver (Ag), and roentgenium (Rg).

21. The method of claim 20, wherein the forming the light-emitting elements and the connecting electrodes, comprises defining the light-emitting element regions by performing a primary etching process on the light-emitting material layer using the double mask patterns, defining the connecting electrode regions by performing a secondary etching process on the connecting electrode layer, and forming the light-emitting elements and the connecting electrodes by performing a tertiary etching process on the light-emitting material layer and the connecting electrode regions.

22. The method of claim 21, wherein:
the first substrate further comprises a first insulating layer between the pixel electrodes, and
the first insulating layer is formed to have a stepped structure by the tertiary etching process.

23. The method of claim 22, wherein:
the first insulating layer includes first areas overlapping with the connecting electrodes and second areas not overlapping with the connecting electrodes, and
a thickness of the first areas is greater than a thickness of the second areas.

24. A method of fabricating a display device, comprising:
bonding a first substrate in which a plurality of pixel electrodes is located, and a second substrate on which a light-emitting material layer is located, with a connecting electrode layer and removing the second substrate;
forming photoresist mask patterns having a stepped structure on the light-emitting material layer;
forming light-emitting elements and connecting electrodes by etching the light-emitting material layer along the photoresist mask patterns; and
depositing a common electrode on the light-emitting elements, wherein:
the photoresist mask patterns comprise middle parts and edge parts located along peripheries of the middle parts; and
a thickness of the middle parts is greater than a thickness of the edge parts.

25. The method of claim 24, further comprising, before the depositing the common electrode:
forming a second insulating layer to cover a top surface and side surfaces of each of the light-emitting elements and a top surface and side surfaces of each of the connecting electrodes, wherein:
the second insulating layer includes openings at the top surfaces of the light-emitting elements, and
the common electrode is in contact with the top surfaces of the light-emitting elements through the openings.

26. The method of claim 25, wherein the connecting electrodes comprises a nonvolatile material comprising one or more selected from among gold (Au), copper (Cu), silver (Ag), and roentgenium (Rg).

27. The method of claim 24, wherein the forming the light-emitting elements and the connecting electrodes, comprises defining light-emitting element regions by performing a primary etching process on the light-emitting material layer until the edge parts are removed, defining connecting electrode regions by performing a secondary etching process on the connecting electrode layer, and forming the light-emitting elements and the connecting electrodes by performing a tertiary etching process on the light-emitting material layer and the connecting electrode regions.

28. The method of claim 27, wherein:
a width of the connecting electrodes is greater than a width of the light-emitting elements; and
upper corners of each of the light-emitting elements and upper corners of each of the connecting electrodes are rounded.

29. The method of claim 28, wherein:
the first substrate further comprises a first insulating layer between the pixel electrodes; and
the first insulating layer is formed to have a stepped structure by the tertiary etching process.

30. The method of claim 29, wherein:
the first insulating layer includes first areas overlapping with the connecting electrodes and second areas not overlapping with the connecting electrodes; and
a thickness of the first areas is greater than a thickness of the second areas.
